(19) United States
(12) Patent Application Publication
(10) Pub. No.: US 2013/0250686 A1
(43) Pub. Date: Sep. 26, 2013

(54) SEMICONDUCTOR MEMORY DEVICE, INFORMATION PROCESSING SYSTEM AND CONTROL METHOD

(71) Applicant: KABUSHIKI KAISHA TOSHIBA, Tokyo (JP)

(72) Inventors: Takao MARUKAME, Kanagawa (JP); Atsuhiro Kinoshita, Kanagawa (JP); Takahiro Kurita, Kanagawa (JP)

(73) Assignee: KABUSHIKI KAISHA TOSHIBA, Tokyo (JP)

(21) Appl. No.: 13/762,986

(22) Filed: Feb. 8, 2013

(30) Foreign Application Priority Data
Mar. 26, 2012 (JP) 2012-070322

(51) Int. Cl. G11C 16/08

(52) U.S. Cl. CPC G11C 16/08
USPC 365/185.12; 365/185.11

(57) ABSTRACT

According to an embodiment, a semiconductor memory device includes a first storage unit, a receiving unit, an acquiring unit, and an output control unit. The first storage unit is configured to store a value and address information in which a key address generated on the basis of a key associated with the value and a physical address of the value are associated with each other. The receiving unit is configured to receive a request for acquisition of the value associated with the key. The request contains the key. The acquiring unit is configured to acquire the physical address associated with the key address of the key contained in the request for acquisition on the basis of the address information. The output control unit is configured to acquire the value at the acquired physical address from the first storage unit and output the acquired value in response to the request.

### CROSS-REFERENCE TO RELATED APPLICATION

This application is based upon and claims the benefit of priority from Japanese Patent Application No. 2012-070322, filed on Mar. 26, 2012; the entire contents of which are incorporated herein by reference.

### FIELD

Embodiments described herein relate generally to a semiconductor memory device, an information processing system and a control method.

### BACKGROUND

As examples of storage devices included in general host systems such as computer systems, there are magnetic hard disk drives (HDD), solid state drives (SSD) having nonvolatile semiconductor memories mounted thereon, and embedded NAND flash memories. SSDs and embedded NAND flash memories are classified as storages, but can also be described as memory systems with extended sizes.

Such a memory system includes an interface, a first memory block, a second memory block and a controller, for example. The first memory block stores data. The second memory block is a buffer memory for writing/reading data. The first memory block is a nonvolatile memory that is larger than the second memory block but has a lower access speed. The second memory block is a temporary storage memory for processing an address translation table of the first memory. The second memory block is also used for compensating for the difference between the transmission rate of the interface and the write/read rate of the first memory block.

For example, the first memory block is a nonvolatile flash memory and the second memory block is a volatile DRAM or SRAM. Such a storage type memory system in the related art has a configuration for realizing data write/read functions specifying an address. In particular, in a large memory system such as an SSD, logical addresses and physical addresses are managed separately for flash memory management. The use of two different types of addresses facilitates the management.

Meanwhile, a data read function specifying data is desired for effectively retrieving data such as a text associated with another text, a specific bit pattern in a binary file, a specific pattern in a video file and a distinctive audio pattern in an audio file that are stored in a memory system. Accordingly, a method of storing not only normal data but also metadata associated with the data in addition thereto and referring to the metadata in order to obtain desired data is used.

One method for managing metadata is a key-value store (KVS) in which data have one-to-one or one-to-many relationships. In the KVS, when a key is supplied as a search request, a value associated therewith is then output.

In order to realize the KVS with the system of the related art, however, data input/output processes of expanding data or a plurality of metadata stored in the memory system on a main storage unit (such as a DRAM) of a host system, performing operation thereon by using a central processing unit (CPU), then reading out the data again from the storage (memory system) and checking the data need to be repeated.

### BRIEF DESCRIPTION OF THE DRAWINGS

FIG. 1 is a diagram of hardware of a semiconductor memory device according to a first embodiment;

FIG. 2 is a block diagram of a device controller;

FIG. 3 is a diagram for explaining access using an L2P table;

FIG. 4A is a diagram illustrating an example of a data format in a K2P table;

FIG. 4B is a diagram illustrating an example of a data format in the K2P table;

FIG. 5 is a diagram illustrating an example of managing the K2P table and an L2P table independently of each other;

FIG. 6 is a diagram illustrating an example of managing the K2P table and the L2P table in one table;

FIG. 7 is a diagram for explaining collision between key addresses;

FIG. 8 is a diagram illustrating an example of a data format in a P2K table;

FIG. 9 is a diagram illustrating an example of a data format in a P2L/P2K table;

FIG. 10 is a flowchart of processing when PUT command is received;

FIG. 11 is a flowchart of processing when APPEND command is received;

FIG. 12 is a flowchart of processing when GET command is received;

FIG. 13 is a flowchart of processing when READ command is received;

FIG. 14 is a diagram for explaining data access mechanism when a physical block table is used;

FIG. 15 is a diagram illustrating an example of a data format in a physical block table according to Modification 1;

FIG. 16 is a diagram for explaining Modification 2 in which a multi-level search table;

FIG. 17 is a diagram illustrating an example of a data format in a K2P table according to Modification 3;

FIG. 18 is a diagram for explaining an example in which two types of hash functions are used;

FIG. 19 is a diagram of hardware of a semiconductor memory device according to a second embodiment;

FIG. 20 is a diagram for explaining an example of search using a CAM;

FIG. 21 is a diagram of hardware of a semiconductor memory device according to a third embodiment;

FIG. 22A is a diagram of hardware of a semiconductor memory device according to a fourth embodiment;

FIG. 22B is a diagram of hardware of a semiconductor memory device according to a modification of the fourth embodiment; and

FIG. 23 is a diagram of hardware of a semiconductor memory device according to a fifth embodiment.

### DETAILED DESCRIPTION

According to an embodiment, a semiconductor memory device includes a first storage unit, a receiving unit, an acquiring unit, and an output control unit. The first storage unit is configured to store a value and address information in which a key address generated on the basis of a key associated with the value and a physical address of the value are associated with each other. The receiving unit is configured to receive a request for acquisition of the value associated with the key. The request for acquisition contains the key. The acquiring unit is configured to acquire the physical address associated with the key address of the key contained in the request for acquisition on the basis of the address information. The output control unit is configured to acquire the value at the acquired physical address from the first storage unit and output the acquired value in response to the request for acquisition.

Preferred embodiments of a semiconductor memory device according to the invention will be described below in detail with reference to the accompanying drawings.

In the following description, an SSD is considered as a system of the related art. In the following embodiments, an SSD refers to a storage constituted by a NAND flash-based solid-state memory in a broad sense and also includes a NAND flash memory embedded system. In addition, the SSD in the embodiments also include a storage for a server larger than these systems.

A method for realizing the KVS with the SSD and problems thereof will be described below. For realizing the KVS with an SSD of the related art, data (real data) are saved as a file and metadata as a key-value pair (KVS data) attached to the data are also saved as a file. In other words, what realizes the KVS is an upper system higher than a file system. For example, a file system or an application implemented on an operating system (OS) realizes the KVS. In this case, there is an advantage that the KVS can be realized with a general hardware configuration. In this case, however, the KVS is handled in the same manner as normal data. Thus, read/write operation and search operation of metadata (KVS data) are performed after a KVS data file is read from a main memory (such as a DRAM) by a host system, for example. No further effect than handling of software (SW) can therefore be expected.

Meanwhile, in the read/write process of the SSD, address translation is performed on the basis of the hardware (HW) configuration of the NAND flash memory. The NAND flash memory is accessed in units of a page such as a 4-KB or 8-KB page in read/write operation. Meanwhile, the NAND flash memory is configured to be erased in units called blocks such as 512-KB or 1024-KB blocks each including a plurality of pages.

Normally, since data cannot be updated in one page, updated data are written into a new page. An address management table for managing used pages and unused pages is thus needed. In addition, write addresses are selected randomly so that write operation is not concentrated on one page. A table for translating a physical address (physical page address) that is used to a logical address (logical page address) specified by the host system or a memory controller (which will be described later) is thus needed. This table is a logical-to-physical address translation table, which is commonly called an L2P table. Management of data in the L2P table increases the life of the SSD but, on the other hand, makes the data management mechanism more complex.

A semiconductor memory device in the following embodiments is a nonvolatile memory system including a NAND flash memory, for example, and processes KVS data (key-value information) efficiently and at a high speed by using an address translation table. In addition, a normal address translation table for outputting address specified data and an address translation table for KVS are both used and made to work efficiently. In the following description, a semiconductor memory device may also be referred to as a memory system or a device.

Next, details of KVS data that are common in all embodiments will be described. An address space that can be subjected to memory accesses in a memory system includes a data storage area (real address space) that can be accessed for real data by specifying addresses and a KVS data storage area. The real address space corresponds to the logical address space in the related art, for example. The KVS data storage area is a data area used in the memory system as necessary. A user or a client therefore accesses the data area by a KVS command to an interface of the memory system.

An example of the KVS command will be described here. The following KVS command for an operation request (KVS request) to a KVS is given from a host system to a host interface of the memory system:

PUT command (registration): register a new set (value) associated with a key;

APPEND command (write): append a new element (value) in a set (value) associated with a certain key;

GET command (acquisition): store an element of a set (value) associated with a key in a working memory (or a buffer memory) and return the size thereof; and

READ command: read an element (value) stored in a working memory (or a buffer memory).

The command names may be altered as appropriate. Another command for a KVS request may be added. For example, a command for rearranging elements (values) belonging to a set may be used. In addition, a command for instructing rearrangement of sets (keys) in a K2P table (which will be described later), comparison between elements (values), or the like may be used.

The memory system includes an L2P table and a K2P table. The L2P table is a translation table between logical addresses and physical addresses. The K2P table is a translation table between fixed-length addresses (key addresses) obtained from keys and physical addresses. A device controller (details of which will be described later) that controls the memory system (device) uses these two types of tables appropriately according to a request from the host system and accesses a real address space and KVS data.

Since the K2P table is created as necessary, the K2P table may be absent in the first memory block if the host system has not requested to create the K2P table. As described above, the KVS data and the K2P table are not provided in a fixed manner but can exist in a manner arbitrarily extended or reduced. A user can therefore physical memory spaces that can be accessed at maximum efficiency while arbitrarily handling KVS data.

Management of the KVS data and the K2P table is a function of the device side (local system side). The host system side is thus freed from management of metadata (KVS data).

The actual KVS data and K2P table are stored in physical pages of the first memory block. The KVS data and the K2P table can be accessed through a normal L2P table or can be managed as special areas that cannot be accessed through an L2P table. These features will be described in the embodiments below.

Next, a specific example of processing for retrieving KVS data will be described. In general, the KVS refers to a database management technique in which sets of keys and values are written allowing a value to be read out by specifying a key. In general, the KVS is often used over a network. There is no doubt that the storage of data is a certain local memory or a certain storage system.

Data are read typically by specifying the top address of the memory in which the data are stored and the data length. Data addresses are managed in units of a 512-byte sector, for example, by an OS or a file system of the host system. Alternatively, if the file system need not be limited, data addresses may be managed in units of 4-KB or 8-KB in conformity with the read/write page size of the NAND flash memory, for example.

Most simple search procedures are as the following (1) to (3).

(1) Convert a key to a fixed-length data by a hash function or the like and translate the fixed-length data to an address of an available memory to obtain a fixed-length address. Set the fixed-length address resulting from the translation to a key address.
(2) Refer to a K2P table saved in a NAND flash memory to obtain a physical address.
(3) Read data at the physical address and output the read data to outside of the memory system.

Such relationships between real data addresses and KVS data and relationships between keys and values correspond to relationships between elements and sets. Specifically, in a typical file, when a file with a file name of “a-file.txt” is a set and there is text data of “This is a book” in the file, for example, each word thereof is an element.

In the case of key/value, the relationships between sets and elements may be reversed and rearranged. That is, the relationships may be converted to “inverted” relationships and saved. For example, in a set of “book”, file names of “a-file.txt” and “b-file.txt” are saved as elements. In the case of key/value, the rearranged set name (“book”) is searched for and elements (“a-file.txt”, “b-file.txt”) thereof are requested. These are practically procedures of creation of inverted files and search typically performed in full-text search and can be said to be one practical example of key/value.

An inverted file is an index file for search used in inverted indexing that is one of methods for realizing full-text search functions. In the inverted indexing, index data files called inverted files in which a list of files containing a content is stored for each content are created in advance. Then, contents of the inverted files are updated each time a file is added/deleted. In response to a content search request, contents of an inverted file corresponding to the content to be searched for may be output as a search result. It is therefore not necessary to check the contents of all the files each time full-text search is performed. The search can therefore be performed at a higher speed. An inverted file is one example of KVS data. The KVS in the embodiments is not limited to inverted files. Furthermore, the embodiments are not technologies specialized in full-text search.

Details of the embodiments will be described below.

### First Embodiment

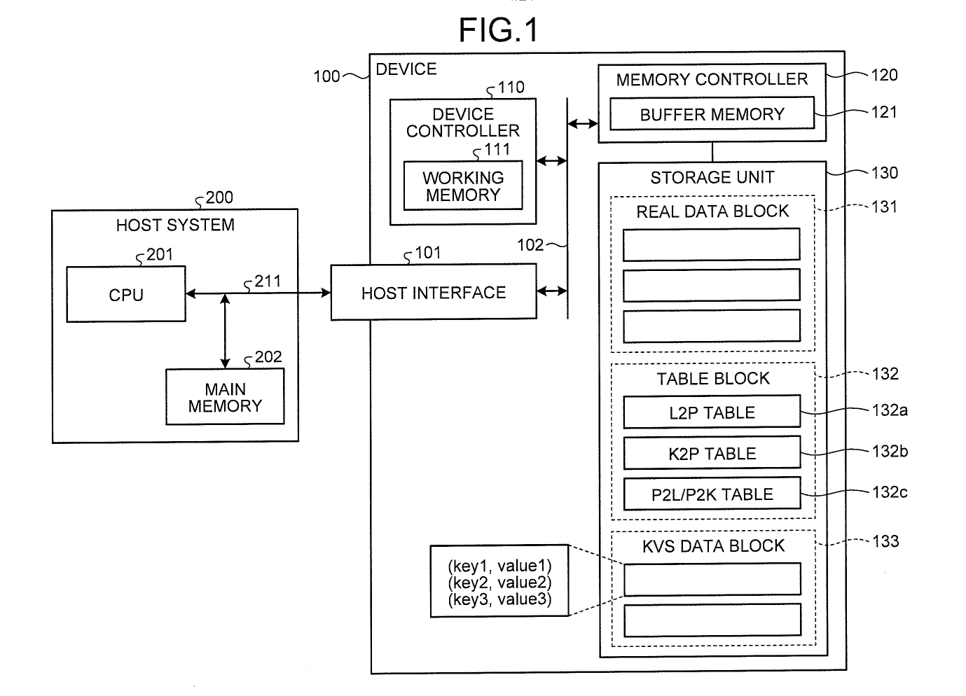

FIG. 1 is a block diagram illustrating an example of hardware configurations of a device 100 that is a semiconductor memory device and a host system 200 according to a first embodiment. As illustrated in FIG. 1, the host system 200 includes a CPU 201, a main memory 202, and a bus 211 that connects the CPU 201 and the main memory 202.

The device 100 includes a host interface 101, a device controller 110, a memory controller 120 and a storage unit 130.

The host interface 101, the device controller 110 and the memory controller 120 are connected via a bus 102. In the device 100, a high-speed and efficient bus line arrangement is desirable. In the meantime, two or more types of bus lines may be used in the device 100 owing to a difference between interface standards and external interface standards, for example.

The host system 200 is connected to the host interface 101 via the bus 211 such as Advanced Microcontroller Bus Architecture (AMBA). The host interface 101 is appropriately selected from Serial Advanced Technology Attachment (SATA), PCI Express, embedded MMC (eMMC), Universal Flash Storage (UFS), Universal Serial Bus (USB) and the like.

The host interface 101 can received a normal data operation request and a KVS request specifying an address from the host system 200.

The storage unit 130 that corresponds to a first memory block includes a real data block 131, a table block 132 and a KVS data block 133. The real data block 131 represents a block in which real data are stored. The table block 132 represents a block in which various tables are stored. The KVS data block 133 represents a block in which KVS data are stored.

The table block 132 stores an L2P table 132a, a K2P table 132b, and a P2L/P2K table 132c, for example. The KVS data block 133 stores KVS data extracted from real data, for example. As will be described data, a physical address of a value associated with a key can be specified by using the K2P table 132b. Thus, KVS data only need to contain at least a value and need not contain a key.

In order to process a KVS request, it is sufficient if at least the K2P table 132b is stored. The P2L/P2K table 132c is a reverse lookup table (details of which will be described later) used for adding and modifying real data and KVS data. If the L2P table 132a is not included, only a reverse lookup table (P2K table) corresponding to the K2P table 132b may be included.

The storage unit 130 is a NAND flash memory that is a nonvolatile semiconductor memory, for example. The storage unit 130 may be constituted by a plurality of chips so as to increase the storage capacity. The storage unit 130 is not limited to the above, and any storage medium can be applied thereto as long as it is a semiconductor memory having a memory nonvolatility. Examples of the storage unit 130 include nonvolatile memories such as a magnetoresistive random access memory (MRAM), a resistance random access memory (ReRAM), a ferroelectric random access memory (FeRAM), and a phase-change random access memory (PCRAM).

The KVS data are stored as a list of keys that are metadata associated with data and top addresses of real data addresses of associated data. The KVS data can be used to create an inverted file as described above or the like.

The memory controller 120 receives a write/read request to the storage unit 130 and controls access to the storage unit 130 according to the write/read request. The memory controller 120 includes a buffer memory 121 that is a second memory block used temporarily for performing write or read. The buffer memory 121 may have a computing function for controlling multi-valued operation of the storage unit 130, for example. The memory controller 120 and the storage unit 130 are connected close to each other and can be integrated in one chip. Even if the memory controller 120 and the storage unit 130 are on separate chips, these can be accommodated in one package. The computing function for controlling multi-valued operation of the storage unit 130 may be provided within the storage unit 130.

The device controller 110 controls signal transmission/reception to/from the storage unit 130 via the host interface 101 and the memory controller 120. The device controller 110 includes a working memory 111 such as a RAM.

The device controller 110 may have a function of error correction coding/decoding (ECC) of data output from the storage unit 130. The device controller 110 can also perform logical-to-physical address translation for the storage unit 130. The ECC function may be provided to the memory controller 120. Similarly, the ECC function may be provided to the storage unit 130. Two or more ECC functions may be provided to different blocks. In the present embodiments, it is assumed that the memory controller 120 has the ECC function and that data are subjected to ECC processing before being transmitted to the device controller in reading the data.

The buffer memory 121 of the memory controller 120 may be used for such processing. The second memory block corresponding to the buffer memory 121 need not necessarily be included in the memory controller 120 but may be connected externally to the device controller 110 via a bus line. The second memory block is not essential and the configuration may be without the second memory block (buffer memory 121). If, however, the device controller 110 can use the second memory block, the device controller 110 can read the KVS data in the storage unit 130 out into the second memory block and refer to the read KVS data.

The second memory block is a storage medium that is volatile and has a smaller capacity but a higher access speed than the storage unit 130, for example. For example, the second memory block is a volatile DRAM or SRAM. Alternatively, the second memory block may be a nonvolatile MRAM as long as equivalent speed and capacity can be provided.

The second memory block is used to compensate for the difference between the transmission rate of the host interface 101 and the access speed of the storage unit 130. A memory system in which a flash memory is used for the storage unit 130 typically has a wear leveling (memory cell lifetime leveling) function by using the device controller 110, the second memory block and the L2P table 132a. Such a wear leveling function may be provided in each of the embodiments.

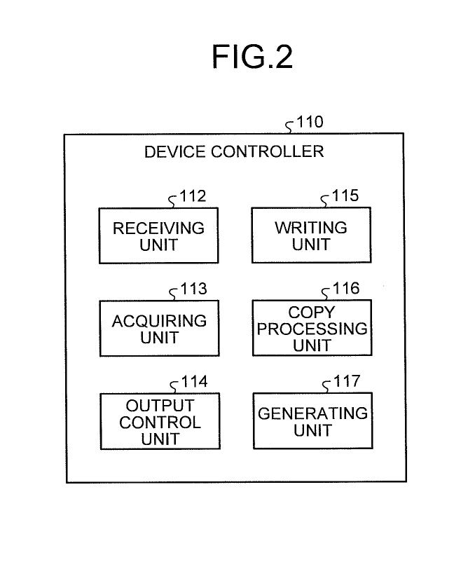

FIG. 2 is a block diagram illustrating an example of a functional configuration of the device controller 110. As illustrated in FIG. 2, the device controller 110 includes a receiving unit 112, an acquiring unit 113, an output control unit 114, a writing unit 115, a copy processing unit 116, and a generating unit 117.

The receiving unit 112 receives a request for acquiring a value associated with a key.

The acquiring unit 113 reads various data from the storage unit 130. For example, the acquiring unit 113 acquires a physical address of a value associated with a key address of a key contained in an acquisition request by using the K2P table 132b stored in the storage unit 130. The acquiring unit 113 also reads out a value of a physical address from KVS data.

The writing unit 115 writes various data into the storage unit 130. The writing unit 115 may have the wear leveling function. For example, the writing unit 115 may be configured to refer to the numbers of rewrites (rewrite frequency) stored in the P2K table and use physical pages in ascending order of the number of rewrites.

The output control unit 114 outputs the read value as a response to the acquisition request.

The copy processing unit 116 performs garbage collection and compaction. Garbage collection is processing to rearrange unused pages in a block. Compaction is processing to gather scattered unused pages into one physical block to reserve an empty block.

The generating unit 117 generates a key address of a fixed length associated with a key. The generating unit 117 can be realized by an electronic circuit having a function of generating a hash function, for example. This electronic circuit may be either a dedicated circuit or a general-purpose circuit to which a hash function algorithm is input. A data storage method and a search method using a hash function will be described later.

All or some of the units illustrated in FIG. 2 may be realized by hardware circuits or may be realized by software (program) executed by a CPU included in the device controller 110.

The program is embedded in a ROM or the like in advance and provided therefrom. Alternatively, a specification in which the program is read as system data from the first memory block when the device is started may be used.

This program may also be recorded on a computer readable recording medium such as a compact disk read only memory (CD-ROM), a flexible disk (FD), a compact disk recordable (CD-R), and a digital versatile disk (DVD) in a form of a file that can be installed or executed, and provided as a computer program product.

Alternatively, this program may be stored on a computer system connected to a network such as the Internet, and provided by being downloaded via the network. Still alternatively, this program may be provided or distributed through a network such as the Internet.

This program has a modular structure including the respective units described above. In an actual hardware configuration, a CPU (processor) reads the program from the storage medium mentioned above and executes the program, whereby the respective units are loaded on a main storage device and generated thereon.

Next, a method of creating a key address by using a hash function will be described. If the device controller 110 includes a function of generating a hash function or a CPU that can execute a hash function algorithm, the device controller 110 can convert arbitrary-length bit data to fixed-length bit data by a hash function. An example in which the generating unit 117 generates a key address of fixed-length bit data from arbitrary-length bit data by using this function will be described here.

As the hash function, a cryptographical hash function with as uniform and sparse distribution as possible is preferable. For example, SHA-1 (secure hash algorithm-1), SHA-2 (secure hash algorithm-2), MD4 (MessageDigest4), MD5 (MessageDigest5), and the like are used.

If conversion is performed by using MD5, “abcd” is converted to “e2fc714c4727ee9395f324cd2e7f331f (hexadecimal number)” having a length of 16 bytes, that is, 128 bits. Similarly, a specific fixed-length data pattern can be obtained when conversion is performed by using an algorithm such as the SHA-1 algorithm

The generating unit 117 has a function of shortening a bit string of certain fixed-length bits generated according to a hash function to a desired bit length. For example, the generating unit 117 has a dividing function represented by the following equation:

<KeyID>=hash(<Key>)mod BitLength.

The generating unit 117 shortens a bit string in this manner by using bit division or division and remainder calculation in this manner. The generating unit 117 may simply cut out and use a desired length from the beginning of the generated bit string of fixed length bits. If 32 bits are cut out from 128 bits in the example above, “e2fc714c (hexadecimal number)” is obtained. Furthermore, address lengths are made uniform in units of addresses of a memory in which KVS are to be stored. For example, lower 8 bits are rounded down to obtain “e2fc7140 (hexadecimal number)”. This becomes the key address.

If the length of the key address thus generated is made equal to that of logical addresses in the L2P table 132a, a method for managing the L2P table 132a can be used without any change. In other words, the key address can be translated to a physical address similarly to a method of translating a logical address to a physical address.

Even when a hash function is used, the probability of the problem that hash values obtained from different data are the same, that is, so-called hash collision does not mathematically become zero.

As a simple method for generating a fixed-length string from an arbitrary-length string other than those using a hash function, a method of generating a fixed-length string by cutting out several bytes from the beginning such as “bo” from “book”, “bl” from “blue” and “no” from “note”, and converting the cut part using an ASCII code to obtain “0x62, 0x6f” for “bo (1-byte character)”, for example, may be used. In this case, however, attention should be paid since there still is a possibility of collision.

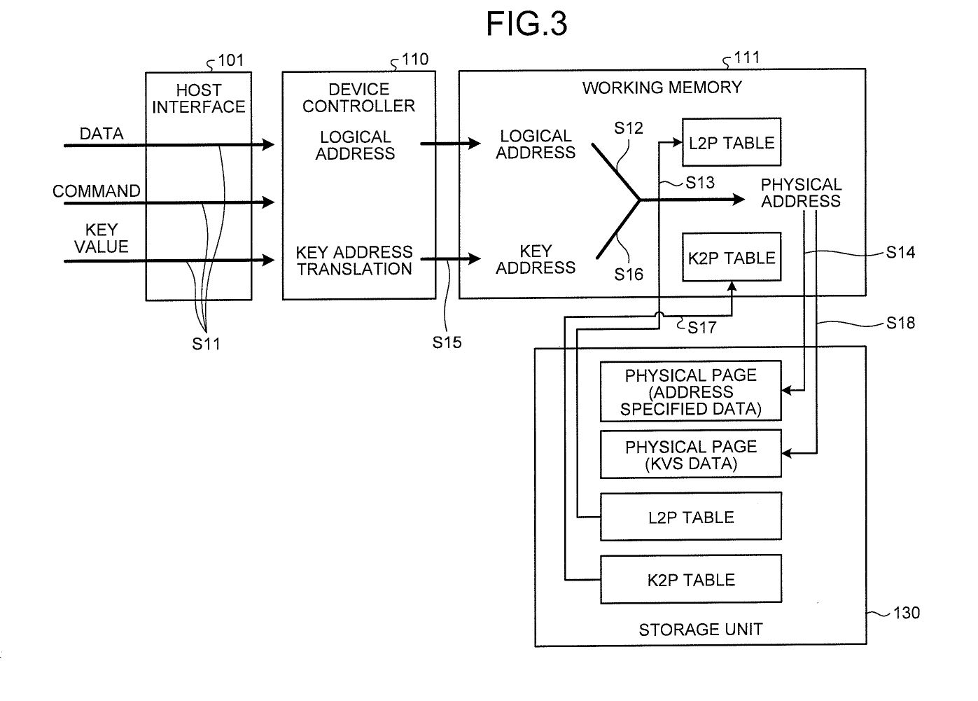

A typical mechanism of data access using the L2P table 132a will be described here with reference to FIG. 3.

Data access to the device 100 such as an SSD is performed by receiving a command at the host interface 101 and interpreting the command by the device controller 110 (step S11).

In a case of the APPEND command, for example, data to be written are transmitted together with the command via the host interface 101. The data are stored in a RAM (such as the working memory 111) that can be accessed by the device controller 110.

In a case of executing the READ command, for example, the device controller 110 uses the L2P table 132a read in advance into the working memory 111 to translate a logical address specified in the command to a physical address (step S12).

If the logical address to be read is not present in the L2P table 132a read into the working memory 111, the device controller 110 reads the L2P table 132a saved in the storage unit 130 and stores the L2P table 132a in the working memory 111 (step S13). Subsequently, the device controller 110 uses the L2P table 132a stored in the working memory 111 to translate the logical address to the physical address. The device controller 110 specifies the obtained physical address to access a physical page in the storage unit 130 and read the data therefrom (step S14).

As described above, KVS data are also managed as normal data in the related art. Accordingly, for reading KVS data, a management file (inverted file) for KVS is first read out by using the L2P table 132a through normal access and KVS data stored in a specific file are then read based on the management file. Furthermore, the L2P table 132a also needs to be referred to for reading the KVS data. After all, it is therefore necessary to access the L2P table 132a twice or more times.

In the present embodiment, therefore, KVS data can be accessed by using the K2P table 132b that is an address translation table similar to the L2P table 132a. The mechanism of access to KVS data by using the K2P table 132b will be described with reference to FIG. 3.

Data access to the device 100 according to the present embodiment is performed by receiving a KVS command at the host interface 101 and interpreting the KVS command by the device controller 110 (step S11).

When the KVS command is the PUT command, for example, data to be registered are transmitted together with the KVS command via the host interface 101 and placed in a RAM (such as the working memory 111) that can be accessed by the device controller 110. The data to be registered may be stored in the working memory 111 similarly to normal data or may be stored in another memory that is a buffer before being stored into the storage unit 130. For simplicity of the explanation, it is assumed that the data are stored in the working memory 111.

As described above, in the present embodiment, the device controller 110 has a mechanism (generating unit 117) for converting a key that is part of the data to an address (key address). For example, when the GET command corresponding to a request for acquiring a value associated with a key is to be executed, the generating unit 117 generates a key address from the key specified in the GET command (step S15). The device controller 110 performs translation between the key address and a physical address in the working memory 111 on the basis of the key address (step S16).

If the key address to be read is not present in the K2P table 132b read into the working memory 111, the device controller 110 reads the K2P table 132b saved in the storage unit 130 and stores the K2P table 132b in the working memory 111 (step S17). Subsequently, the device controller 110 uses the K2P table 132b stored in the working memory 111 to translate the key address to a physical address. The device controller 110 specifies the obtained physical address to access a physical page in the storage unit 130 and read the KVS data therefrom (step S18).

According to the present embodiment, since KVS data are managed in the K2P table 132b, a physical address in the storage unit 130 can be directly referred to without accessing to the L2P table 132a in order to read KVS data. As a result, the access speed to KVS data can be increased.

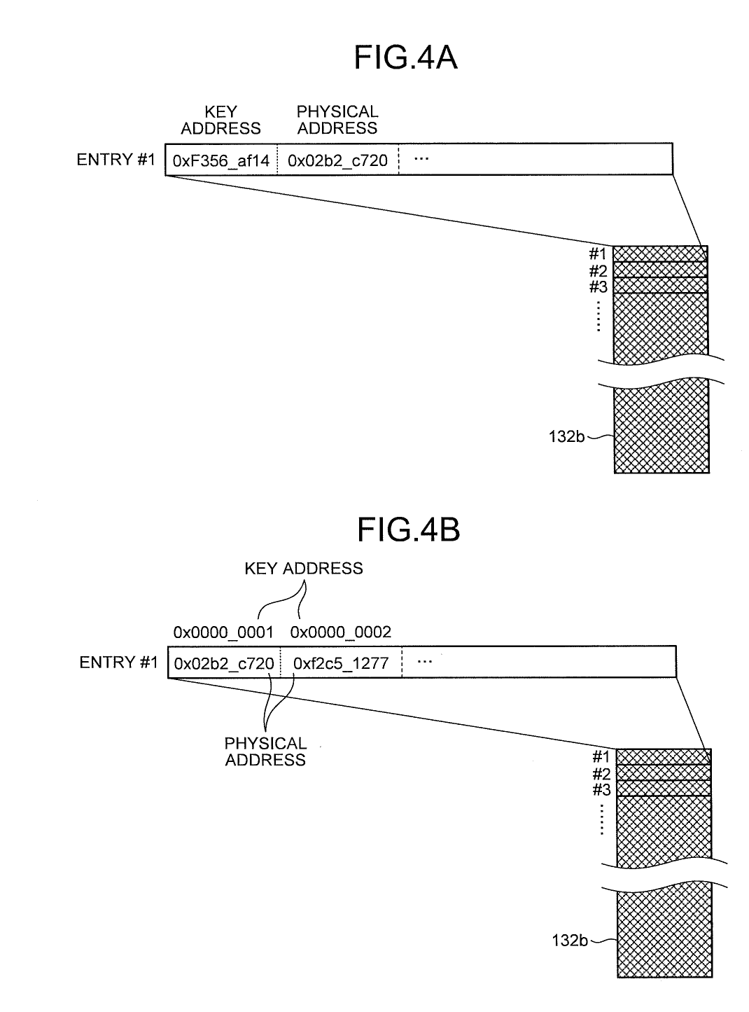

FIG. 4A is a diagram illustrating an example of a data format in the K2P table 132b. The K2P table 132b has a table data format containing a plurality of entries. An entry contains at least a piece of address information (K2P pair) that is association of a key address and a physical address. For example, the K2P table 132b stores 8-byte K2P pairs, each being a pair of a 32-bit (4-byte) key address and a 32-bit (4-byte) physical address. The address lengths are only an example, and may be modified as necessary according to the system size.

FIG. 4A illustrates an example in which key addresses are stored in the K2P table. The order in which addresses of entries are saved may be according to key address values as in FIG. 4B. As a result, it is possible to save the space corresponding to that for saving key addresses. In the example of FIG. 4B, the physical addresses (4 bytes) only need to be saved, and the required amount of memory for the K2P table is half the amount in the case of FIG. 4A.

The number of K2P pairs per one entry may be determined taking the speed and the easiness of design into account on the basis of the specification of the device controller 110 that accesses the K2P table 132b, the specification of the working memory 111, the page size of the storage unit 130 and the like. When the size of K2P pairs is 8 bytes, for example, and the K2P table 132b is managed in units of 8 KB, 1000 K2P pairs are stored per one entry. Alternatively, when the K2P table 132b is managed in units of 256 B per one entry, for example, 32 K2P pairs are stored in one entry.

The K2P table 132b can have arbitrary extensibility with generation of key addresses. For example, when key addresses are generated in response to requests of KVS commands from the host system 200, K2P pairs can be created in the order of the generation.

In this case, the original K2P table 132b is small but random key addresses are stored therein in the order of the generation. Accordingly, if a K2P pair is searched for in this state, the time for the search may be increased. Thus, in order to increase the search speed, a table for searching for a K2P pair may further be provided.

Conversely, the K2P table 132b may originally be set to a fixed size. In the first place, if there is no possibility of adding the amount of memory of the storage unit 130 in the device 100, that is, if there is no extensibility, the total number of physical pages is already defined. For this reason, the sized of the K2P table 132b may originally be fixed. For example, when the size of a K2P pair is 8 bytes and one entry corresponds to 8 KB, physical address data for 1000 pages are stored per one entry. When the storage capacity of the storage unit 130 is 8 GB and the page size is 8 KB, 1,000,000 pages will be present. Accordingly, the K2P table 132b only needs to be capable of storing 1,000 entries. In this case, the size of the K2P table 132b will be 8 MB.

The format to be employed can be determined by taking the size and the extensibility of the device 100 into account.

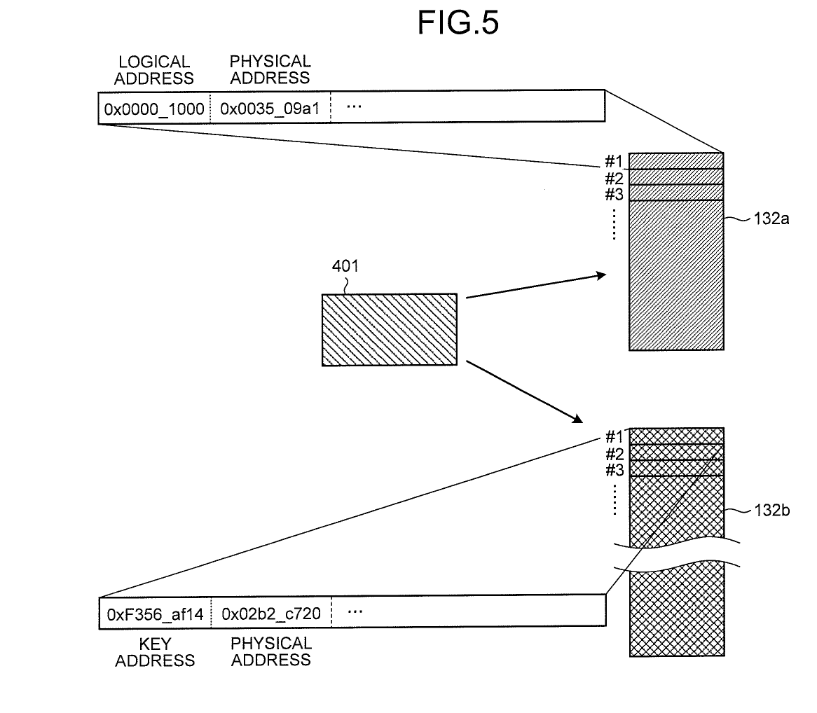

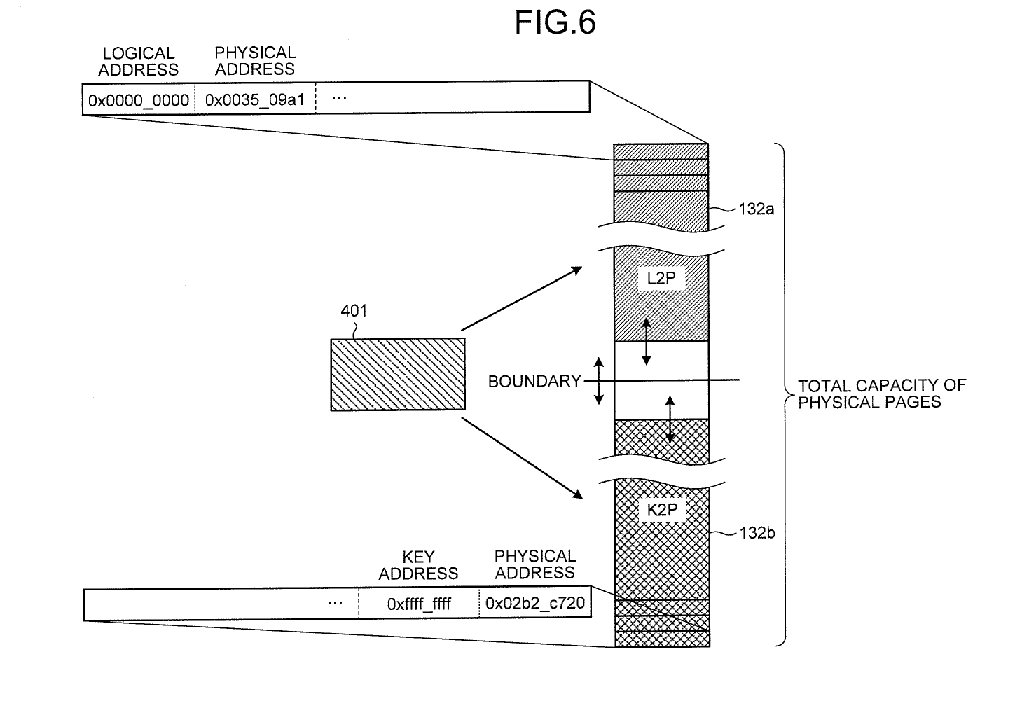

Next, methods for managing the K2P table 132b and the L2P table 132a will be described with reference to FIGS. 5 and 6. FIG. 5 illustrates an example of managing the K2P table 132b and the L2P table 132a independently of each other.

In the present embodiment, when the device 100 has the L2P table 132a for handing normal data, the same data formal is used for the L2P table 132a and the K2P table 132b. As a result, it is possible to use common algorithms and commands in the device controller 110 and reduce additionally required hardware.

For example, the L2P table 132a stores pairs each of 8 bytes in total of a logical address of 32 bits (4 bytes) and a physical address of 32 bits (4 bytes). Similarly, the K2P table 132b stores pairs (K2P pairs) each of 8 bytes in total of a key address of 32 bits (4 bytes) and a physical address of 32 bits (4 bytes).

The device controller 110 determines whether an address to be handled is an address in the L2P table 132a or an address in the K2P table 132b by using a classifying function 401. The device controller 110 can process both addresses in the same manner after the determination.

When “0x0000_{—}1000” is referred to as an address value and it is determined by the classifying function 401 that the address is a logical address of normal data as in FIG. 5, for example, the device controller 110 refers to the L2P table 132a.

Alternatively, when “0xF356_af14” is referred to as an address value and it is determined by the classifying function 401 that the address is a key address, the device controller 110 refers to the K2P table 132b. Processing after a physical address is obtained by referring to any of the tables is basically the same in the cases of the L2P table 132a and the K2P table 132b.

The classifying function 401 can be realized by several methods. A first one of such methods is a method of reading the K2P table 132b if a request (command) from the host system 200 held by the device controller 110 is a K2P command or reading the L2P table 132a if the request (command) is a command specifying a normal data address.

A second method for the classifying function 401 is a method of providing a table (classification table) for classification in advance and determining which of a logical address and a key address to be referred to. When the classification table is used, it is necessary to manage the addresses at the point when a key address is generated so that a logical address and a key address do not collide with each other. For example, it is assumed here that “0x0000_{—}1000” is already used as a logical address and a generated key address is “0x0000_{—}1000” by accident. In this case, since the addresses collide with each other, it is determined in the classification table that the address is a key address and the K2P table 132b is to be read. The classifying function 401 can be selected by the manufacturer according to design requirements of the device controller 110.

The classification table sets a pair of an address value and a value representing the status of use as an entry, for example. When an address is supplied, the classification table can be search to check whether the address is used as a logical address or a physical address. Since, however, the device controller 110 knows whether normal read/write specifying an address is a KVS command in advance, the classification table is not necessarily needed.

FIG. 6 illustrates an example of managing the K2P table 132b and the L2P table 132a as one general table.

For example, the number of 32-bit logical addresses to be used in the L2P table 132a is limited in advance to a predetermined size such as up to “0x1000_{—}0000”. Then, an address equal to or greater than “0x1000_{—}0001” is determined to be a key address. The device controller 110 may be capable of managing the address value that is a boundary. FIG. 6 illustrates an example in which key addresses correspond to a second half of addresses in the general table.

In the method as illustrated in FIG. 6, the classifying function 401 can know whether the table to be accessed is the L2P table 132a or the K2P table 132b by determining whether an address in the general table is in the first half or in the second half with respect to the predetermined boundary.

The method of FIG. 6 and the method of using the classification table described above may be used in combination. A table having a size capable of storing addresses of all physical pages in the memory system is provided as the general table.

Next, collision between key addresses generated by the generating unit 117 will be described.

In general, the number of keys is not limited in a KVS method. Thus, if the number of KVSs stored in the memory system, that is, the number of types of keys is increased, key addresses generated for the keys collide with one another. It is assumed, for example, that a key address for a key that is a word “Blue” is “0x0000_{—}41a9b”. In this case, the probability that a key address generated from a word “Car” that is another key becomes identical to “0x0000_{—}41a9b” by accident is not zero. Even if an advanced hash function is used for generation of key addresses to generate mathematically sparse numbers, there arises a possibility of collision when key address values are converted to smaller size data of a fixed length.

Some methods can be considered for avoiding collision between key addresses as much as possible. A first one of such methods is a method of using key addresses in as long a length as possible. For example, a value resulting from conversion by a hash function may be used as a key address without any change. Since, however, the K2P table 132b becomes larger owing to long addresses, there arise a problem that the amount of memory is consumed accordingly and a problem that the conformity of the data format with the L2P table 132a is undermined. If the capacity of the storage unit 130 can be sufficiently increased and the number of physical pages large enough with respect to the number of types of keys can be provided, the probability of key collision can be decreased. Even in this case, however, the probability of collision cannot be decreased to zero.

A second method is a method of combining two or more methods for converting arbitrary-length data to fixed-length data. For example, when a key address is to be converted to one with a length of 32 bits, a method of generating a part corresponding to 16 bits by a hash function, expressing the remaining 16 bits by binary data obtained by converting the key itself with an ASCII code or the like, and combining the 16-bit data can be used. Since the first half 16-bit value is a random value but the second half 16-bit value is derived from the original data, the probability of key collision can be made as low as possible. Even with this method, however, the possibility of collision is not mathematically zero, and the possibility of collision will increase as the number of keys is increased.

After all, collision of address values generated from keys cannot be avoided because the provided keys have arbitrary lengths and infinite variations unlike logical addresses.

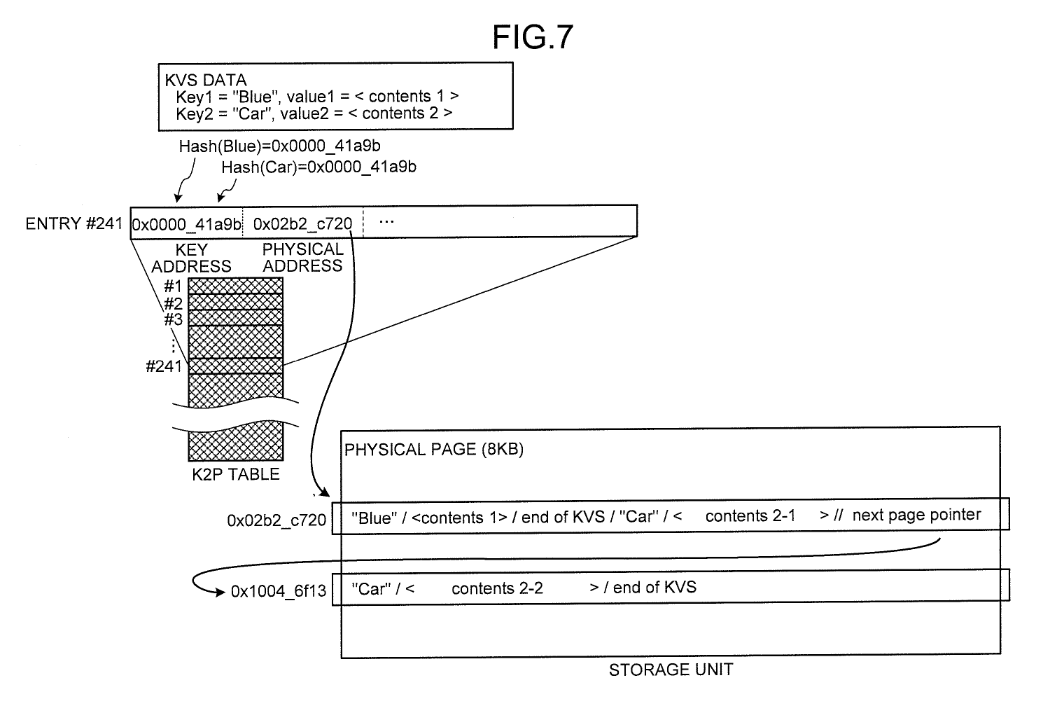

In the present embodiment, therefore, a function capable of correctly reading a value even when collision occurs is provided. FIG. 7 is a diagram schematically illustrating the K2P table 132b and values (value data) stored in a physical page.

The upper part of FIG. 7 illustrates an example of KVS data in which “Key1” is “Blue” and “value1” is a content (value) “<contents 1>” associated thereto. Similarly, an example of KVS data in which “Key2” is “Car” and “value2” is a content “<contents 2>” associated thereto is illustrated.

It is assumed that as a result of generating key addresses by converting “Blue” and “Car” using a hash function by the generating unit 117, these key addresses “0x0000_{—}41a9b” collide with each other. The acquiring unit 113 refers to a physical address associated with the key address and reads out the value data. Values associated with “Key1”=“Blue” and “Key2”=“Car” are saved in the physical page. The acquiring unit 113 reads out the entire physical page into the working memory 111, for example. Subsequently, the device controller 110 or the host system 200 refers to the read physical page and determines whether a value associated with the intended key is saved therein. For example, if the intended key is “Blue”, the device controller 110 or the host system 200 can acquire the value “<contents 1>” associated with “Blue” from the entire physical page that is read. Alternatively, for example, if the intended key is “Car”, the device controller 110 or the host system 200 can acquire the value “<contents 2>” associated with “Car” from the entire physical page that is read. In the example of FIG. 7, “<contents 2>” is divided into “<contents 2-1>” and “<contents 2-2>” and stored separately in two pages. As will be described below, parts of a divided value can be read successively by using a pointer for reading a next page.

In the KVS, since keys and values have arbitrary lengths, data are not always stored within one physical page. Accordingly, as illustrated in FIG. 7, an address (next page address (hereinafter referred to as a next page pointer)) representing a storage location that is a pointer for reading a next page is stored at a specific location in the physical page so that data can be read successively. When KVS data are stored over a plurality of physical pages in this manner, a corresponding number of physical pages are consumed accordingly. In a case of the storage unit 130 using a NAND flash memory, the next page pointer can be stored in an area called a redundant data part or a management data part in one page.

Next, a reverse lookup table will be described. For addition and modification of real data and KVS data, reverse lookup tables of the L2P table 132a and the K2P table 132b, respectively, are needed.

When a NAND flash memory is used as the storage unit 130, the lifetime of memory cells decreases mainly with writes therein. Accordingly, procedures for using physical pages uniformly to make best used of memory cells are used. The technique for prolonging the lifetime by using physical pages uniformly is called wear leveling. Read/write from/into the NAND flash memory is performed typically in units of a page. In addition, erasure of the NAND flash memory is performed in units of a block. Accordingly, if data are concentrated on a specific block, the lifetime of the block is decreased and the reliability also decreases at the same time. Typically, the NAND flash memory often has a specification that does not allow appending to the same page. Accordingly, for altering data written in a physical page, the altered data are written into another physical page and a logical address is associated with the address (physical address) of the physical page.

As described above, a memory system using a NAND flash memory typically includes a P2L table associating physical addresses with logical addresses. In this case, for newly allocating a physical page, which physical page to use is determined on the basis of history indicating which physical page has not been used or which page has the lowest rewrite frequency.

In the present embodiment, physical pages of KVS data are also managed by using the P2K table that is a reverse lookup table of the K2P table 132b by a technique similar to that for managing physical pages by using the P2L table. As a result, the lifetime and the reliability of the device 100 can be increased.

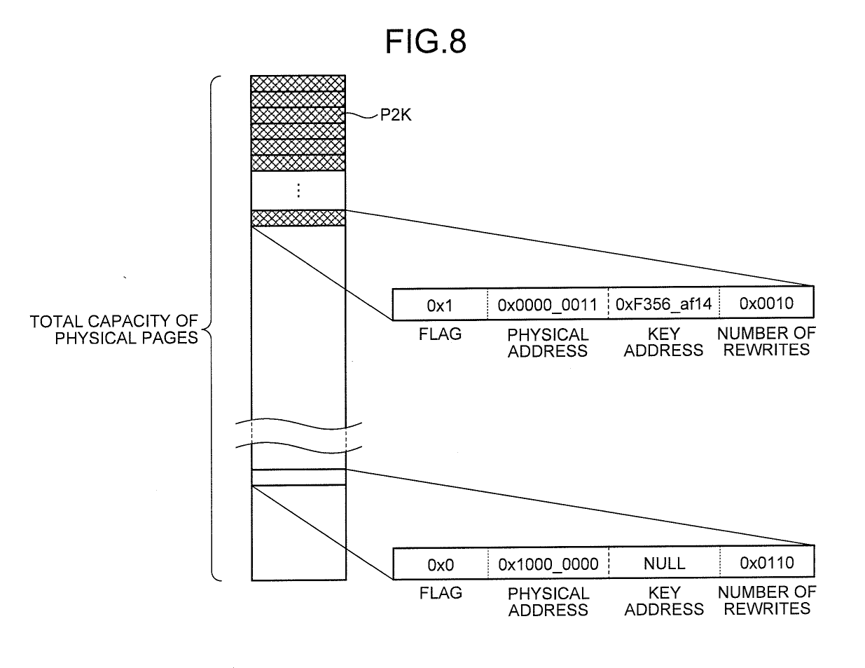

FIG. 8 is a diagram illustrating an example of a data format in the P2K table. The P2K table contains a pair of a physical address and a key address in each entry.

Each entry can contain 1-bit determination information (flag), for example, indicating that the physical address is used. The status of use of a physical address can be determined by referring to the flag. As illustrated in FIG. 8, in the cases of “0x0” and “0x1”, for example, flags indicating that a physical address is not being used and that a physical address is being used, respectively, can be used.

The determination information in FIG. 8 is only an example and the determination information is not limited thereto. Any information indicating whether or not a physical address is being used (whether or not a page represented by a physical address is valid) may be used. The copy processing unit 116 refers to a flag (determination information) in the P2K table to perform garbage collection and compaction. For example, the copy processing unit 116 performs compaction on data in pages represented by physical addresses (being used (being valid)) with flags in the P2K table being “0x1”.

The physical pages can be managed easily by creating the P2K table in advance after K2P pairs are generated. Each entry may contain the number of rewrites (rewrite frequency) on a physical page associated with a physical address. Recording the number of rewrites allows control for selecting and using a physical page with the smallest number of rewrites.

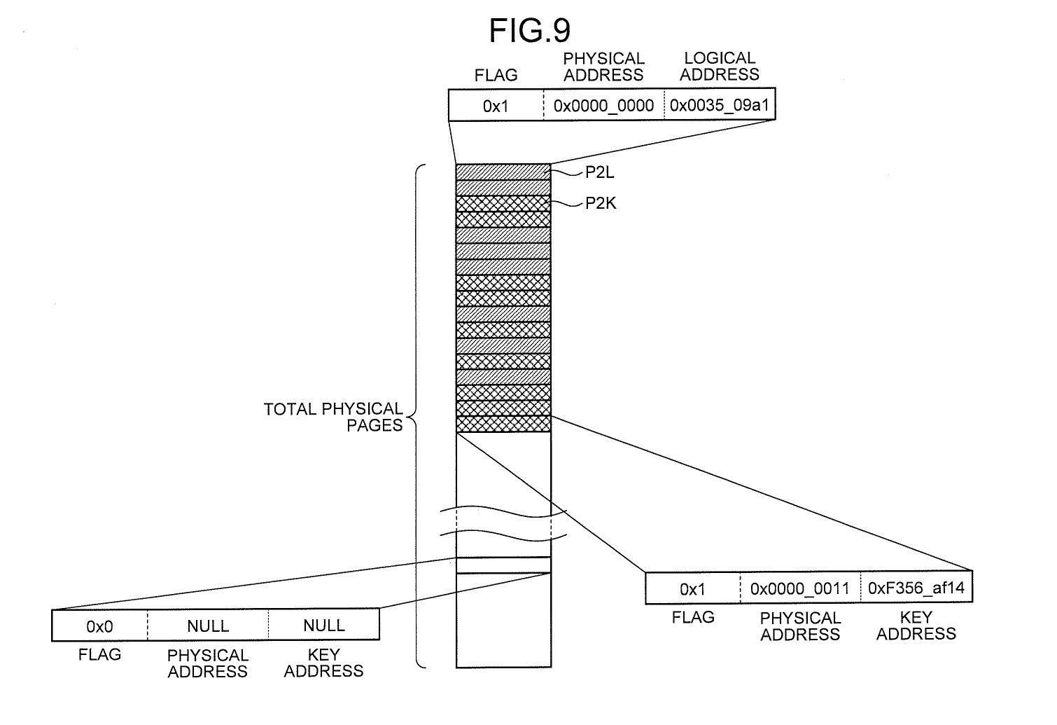

FIG. 9 is a diagram illustrating an example of a data format in a table (P2L/P2K table 132c) uniting the P2L table and the P2K table. With reference to this table, it is possible to know whether a physical address is associated with a logical address or a key address.

When KVS data are stored over a plurality of physical pages as illustrated in FIG. 7, the physical addresses of the respective physical pages and the logical address of the KVS data are also recorded and managed in the P2K table.

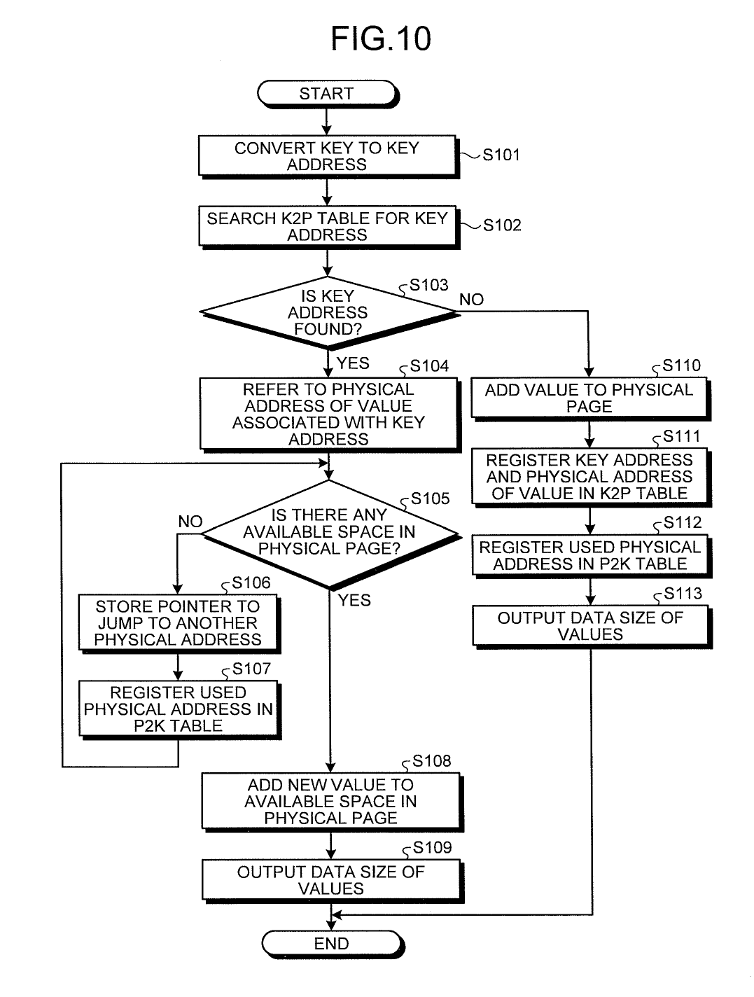

Next, various processes performed by the device 100 thus configured according to the first embodiment will be described with reference to FIGS. 10 to 13. FIG. 10 is a flowchart of an example of processing when the PUT command is received.

When the receiving unit 112 receives the PUT command, the processing of FIG. 10 is started. The PUT command contains KVS data to be registered, for example. The generating unit 117 converts a key contained in the KVS data to be registered to a key address (step S101).

The acquiring unit 113 refers to the K2P table 132b to search whether or not the key address already exists in the K2P table 132b (step S102). The acquiring unit 113 determines whether or not the key address is found in the K2P table 132b (step S103). If the key address is found (Yes in step S103), the acquiring unit 113 refers to a physical address of a value associated with the key address (step S104) to determine whether or not there is a space available in the physical page with the value (step S105). If there is no space available in the physical page with the value (No in step S105), the acquiring unit 113 stores a pointer (next page pointer) for jumping to a next physical address and refers to the physical address (step S106). The acquiring unit 113 refers to at least one of the P2K table and the P2L table to search for an available physical address and determines the physical address to jump to. The writing unit 115 registers the used physical address in the P2K table (step S107).

If there is a space available in the physical page with the value (Yes in step S105), the writing unit 115 appends the value contained in the KVS data to be registered to this physical page (step S108). There are cases, however, in which appending to the same page is prohibited as in the case of a flash memory. In such cases, data (values) are collectively stored in a physical page at another physical address. The output control unit 114 outputs the data size of the values resulting from the appending (step S109), and the processing is terminated.

If the key address is not found in the K2P table 132b in step S103 (No in step S103), the writing unit 115 adds the value to a physical page at an available physical address (step S110). The writing unit 115 registers the key and the physical address of the value in association with each other in the K2P table 132b (step S111). The writing unit 115 registers the used physical address in the P2K table (step S112). The output control unit 114 outputs the data size of the values resulting from the appending (step S113), and the processing is terminated.

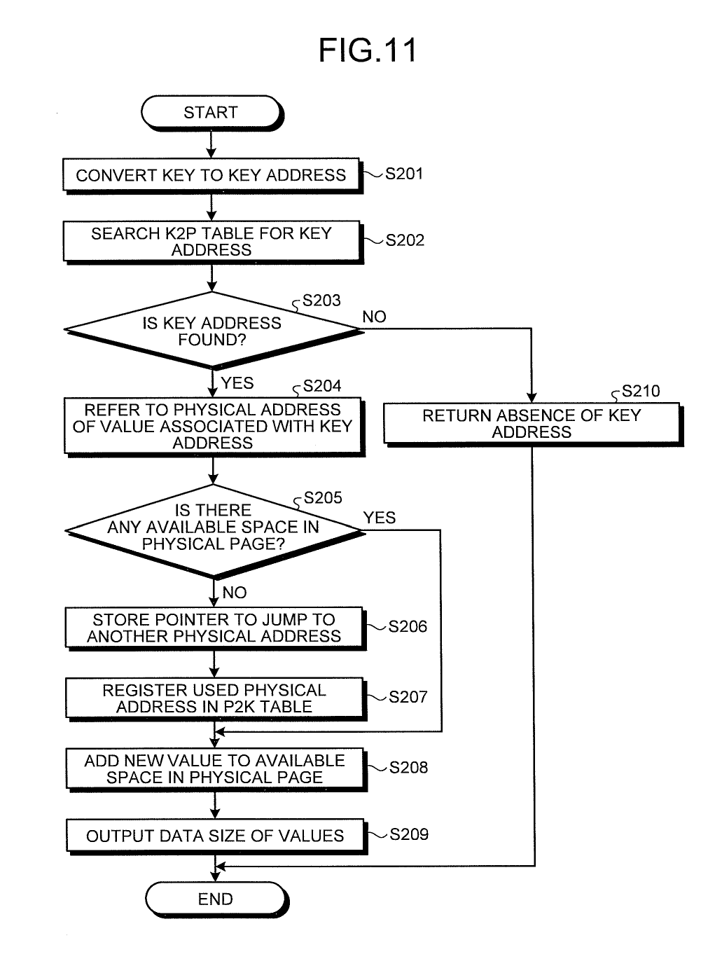

FIG. 11 is a flowchart of an example of processing when the APPEND command is received. When the receiving unit 112 receives the APPEND command, the processing of FIG. 11 is started. The APPEND command contains KVS data, for example. The APPEND command is a command to append a value for an already existing key.

Since steps S201 to S209 are the same as steps S101 to S109 in FIG. 10, the description thereof is not repeated.

If the key address is not found in the K2P table 132b in step S203 (No in step S203), the acquiring unit 113 returns that the key is not present, and the processing is terminated (step S210). The acquiring unit 113 informs that the key is not present by returning SIZE=0, for example.

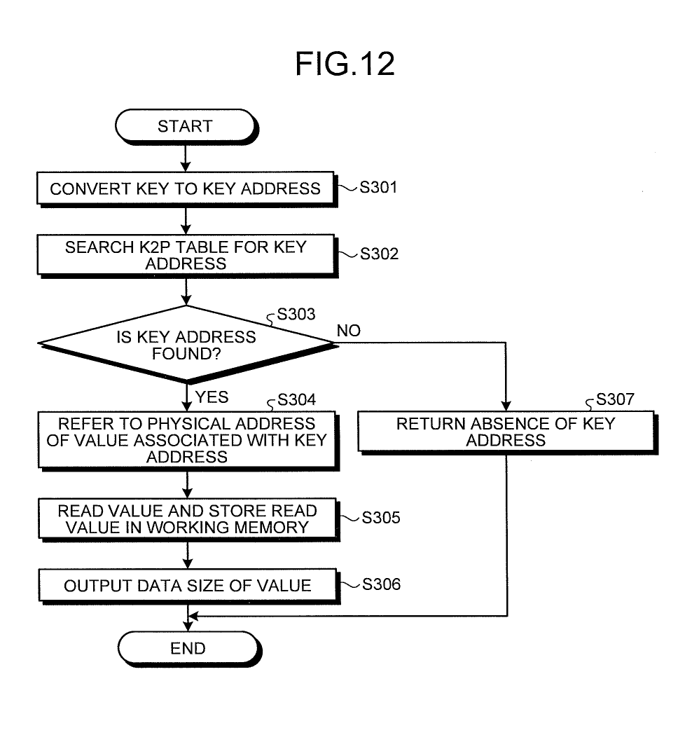

FIG. 12 is a flowchart of an example of processing when the GET command is received. When the receiving unit 112 receives the GET command, the processing of FIG. 12 is started. The GET command contains a key, for example.

Since steps S301 to S303 are the same as steps S101 to S103 in FIG. 10, the description thereof is not repeated.

If the key address is found (Yes in step S303), the acquiring unit 113 refers to a physical address of a value associated with the key address (step S304), reads out the value associated with the key address and stores the read value into the working memory 111 (or the buffer memory 121) (step S305). The output control unit 114 outputs the data size of the read value (step S306), and the processing is terminated.

If the key address is not found in the K2P table 132b in step S303 (No in step S303), the acquiring unit 113 returns that the key is not present, and the processing is terminated (step S307). The acquiring unit 113 informs that the key is not present by returning SIZE=0, for example.

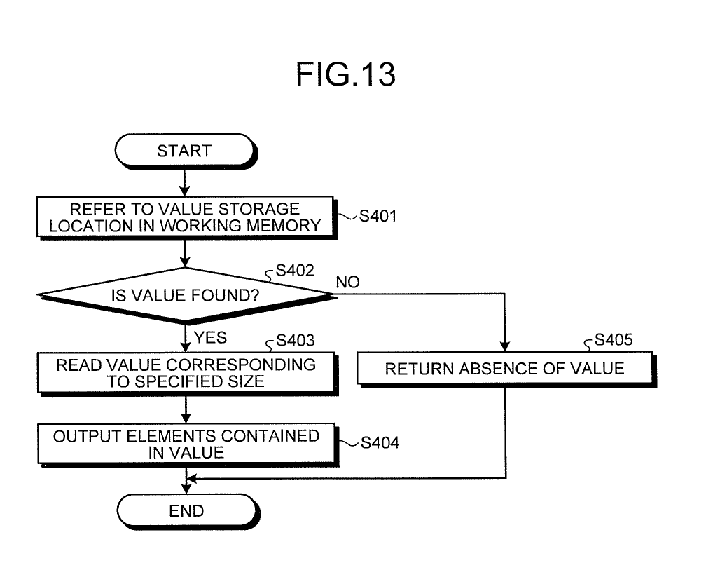

FIG. 13 is a flowchart of an example of processing when the READ command is received. When the receiving unit 112 receives the READ command, the processing of FIG. 13 is started. The READ command contains specification of a size, for example.

The acquiring unit 113 refers to a location in the working memory 111 where elements of a set (value) are stored (step S401), and determines whether or not the value is found in this storage location (step S402). If the elements of the set (value) are not found (No in step S402), the acquiring unit 113 informs that the elements of the set (value) are not present by returning S=NULL, for example, as output (step S405). If the elements of the set (value) are found (Yes in step S402), the acquiring unit 113 reads elements of the set (value) corresponding to the specified size (step S403). The acquiring unit 113 outputs the read elements of the value (step S404), and the processing is terminated.

While only the size is specified in the example of FIG. 13, a location (address) in the working memory 111 may also be specified for reading a value.

Note that actual procedures and commands are not limited to those in the examples illustrated in FIGS. 10 to 13. For example, in a case where a plurality of keys are found, procedures of setting flags indicating the keys are found and reading all values at a time later may be performed.

As described above, according to the present embodiment, the host interface 101 can receive a command or the device controller 110, the memory controller 120 or the like can receive a command via the host interface 101 and perform a series of processes on KVS.

Modification 1

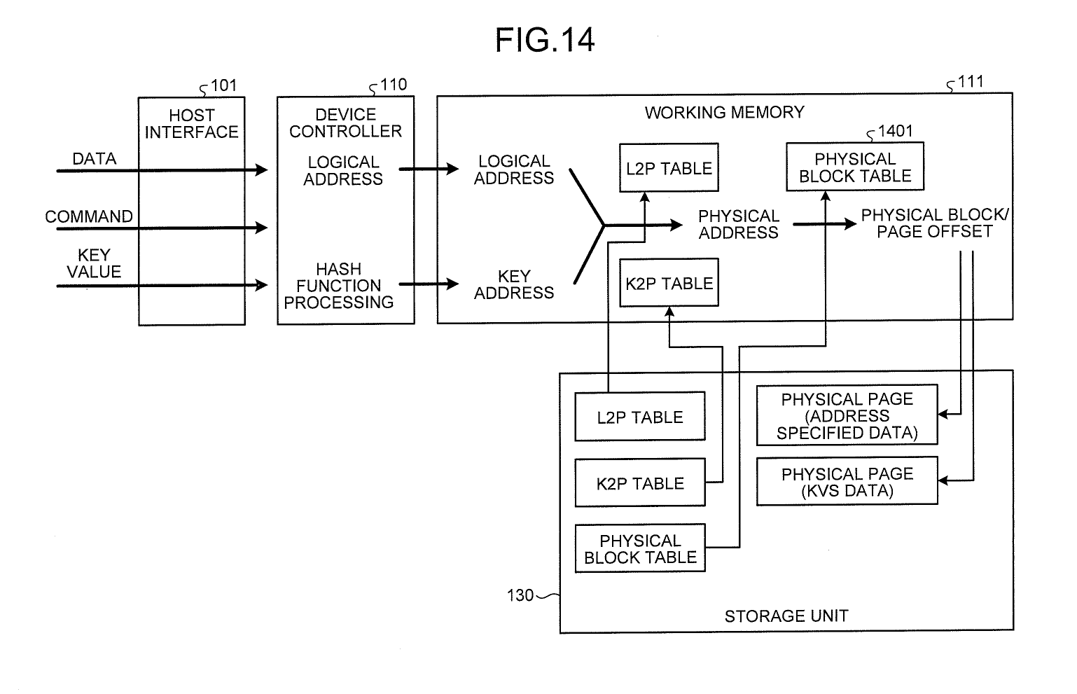

In Modification 1, an example in which a physical block table is used will be described. FIG. 14 is a diagram for explaining data access mechanism when the physical block table is used.

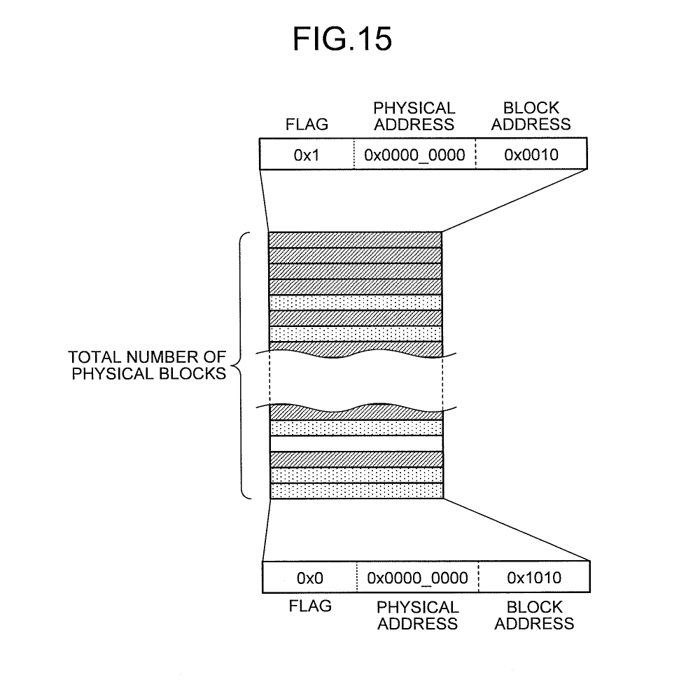

FIG. 14 illustrates an example in which a physical block table 1401 that further translates a physical address to which a logical address is translated to a physical block and a page offset. FIG. 15 is a diagram illustrating an example of a data format in the physical block table. The physical block table of FIG. 15 is used for identifying a physical block to which a page at a physical address corresponds from the physical address. As a result of including such a physical block table, the device 100 in which a NAND flash memory is used as the storage unit 130, for example, can efficiently perform garbage collection and compaction.

What is referred to in the K2P table 132b in the present embodiment is a physical address. Accordingly, as a result of using the physical block table, garbage collection and compaction on KVS data can be handled similarly to those on normal data (real data) in the L2P format. Even the device 100 including both K2P and L2P can therefore generate a highly reliable system in a relatively easy manner.

Modification 2

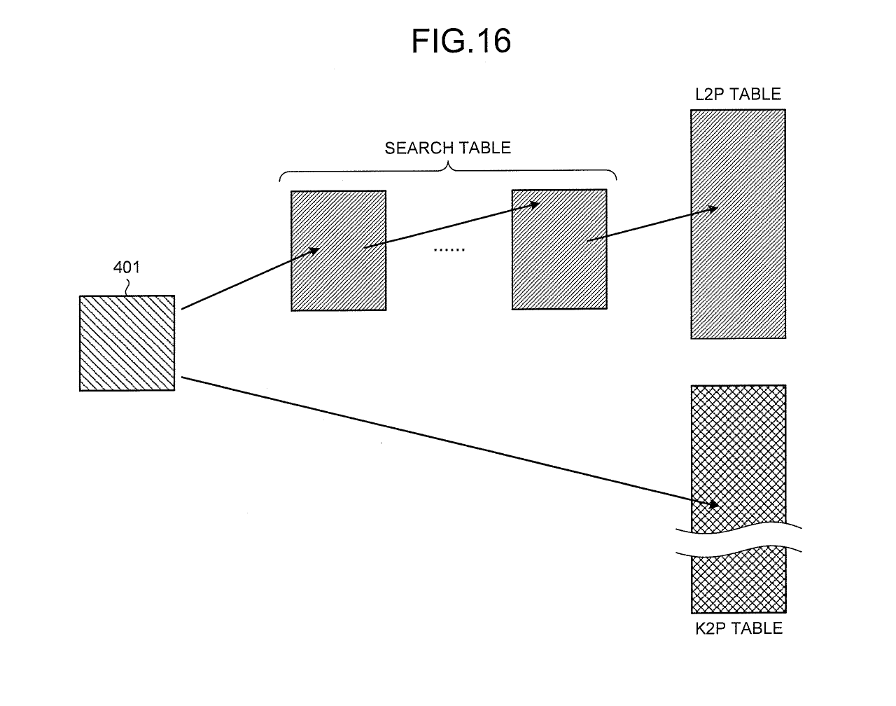

In Modification 2, an example in which an L2P table is accessed by using a multi-level search table will be described. As illustrated in FIG. 16, a configuration in which the classifying function 401 classifies which of a logical address (real data) and a key address (KVS data) to refer to and then one or more search tables are further used to refer to a physical address associated with the logical address may be used.

Since the L2P table stores information on all pages in the storage unit 130, the size thereof becomes larger than the capacity of the working memory 111. When the READ/APPEND command specifying an address is received, the device controller 110 needs to search the first memory block for an entry in the L2P table in which an intended logical address is to be stored.

For example, when the capacity of the storage unit 130 is 64 GB and it is assumed that the capacity of one page is 4 KB, there are 16,000,000 pages in the storage unit 130. If the address unit is 32 bits (4 bytes), the capacity of the L2P table is 64 MB. Since the working memory 111 is typically constituted by an SRAM, the working memory 111 cannot store the entire L2P table. In order to efficiently search the storage unit 130 for the intended L2P entry, a search table for searching for the L2P entry can thus be used. The search table is followed in a tree manner until the intended entry is reached. The search table includes multiple levels according to the number of L2P entries and the capacity of the working memory 111. Since the number of reads of the search table will be increased and the L2P processing speed may become correspondingly lower when the search table includes multiple levels, an appropriate number of levels are used.

In the embodiment described above, since the K2P table 132b can be used alone or can be easily used in combination with the L2P table 132a, the user will not feel an increase in the system load due to the processing on KVS data.

Even when the K2P table 132b and the L2P table 132a are used in combination, use of KVS data can increase the access speed if the K2P table 132b can be referred to by a number of processes that is smaller than that when referring to the L2P table 132a as in FIG. 16.

Note that since the data format of the KVS is employed, data of a value associated with the requested key can be immediately obtained and the search therefore become faster. In the present modification, since access to KVS data can eliminate unnecessary procedures for referring to the L2P, the search becomes even faster. Because a mechanism similar to that for management of the L2P table is used, an increase in the hardware cost as a result of storing KVS data can be suppressed to almost zero.

Modification 3

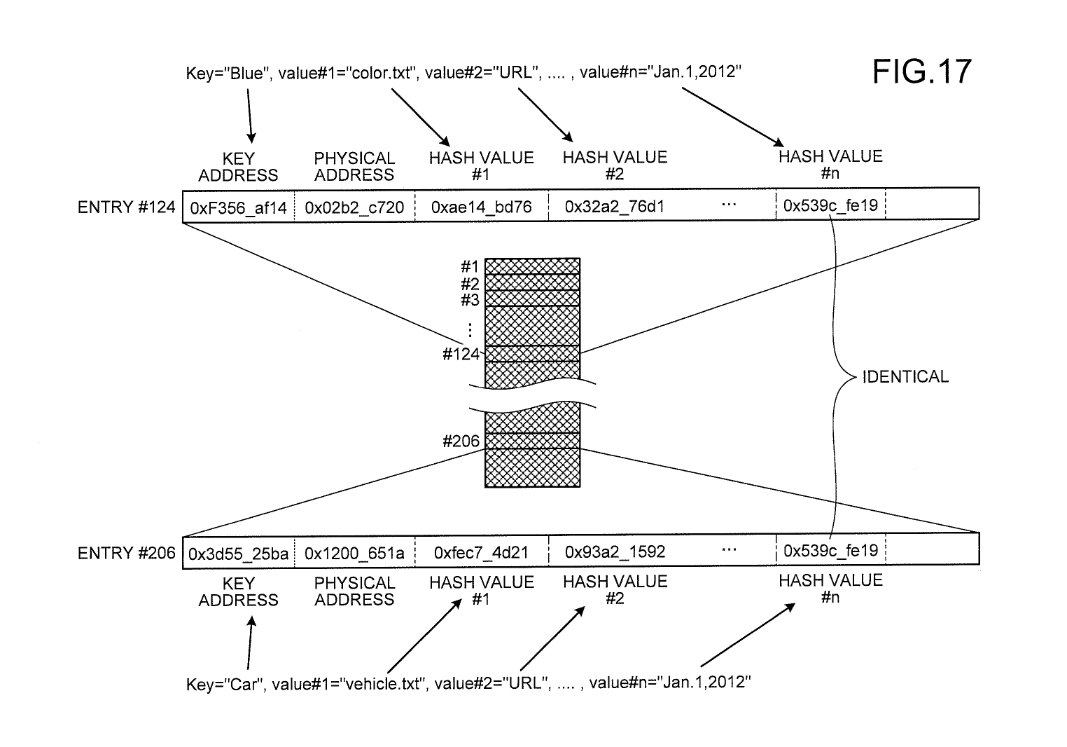

In FIGS. 4A and 4B, examples of the K2P table 132b in which a plurality of associations between key addresses and physical addresses is included in one entry are illustrated. In Modification 3, an example in which the K2P table 132b is extended and a hash value of a value is stored after a physical address will be presented. FIG. 17 is a diagram illustrating an example of a data format in the K2P table 132b according to Modification 3.

When the GET command and a set operation instruction AND, for example, of a KVS request reach the device 100 from the host system 200, the device 100 side can refer to the K2P table 132b containing hash values to determine the content of a value and a set operation thereof in advance before reading the value from the storage unit 130. Since unnecessary reading is reduced, the time for search and set operations can be shortened.

In the KVS, there are cases where a plurality of values is assigned to one key as in this example. The values are saved in a page in the storage unit 130 specified by a physical address without any change. In the example of FIG. 17, all hash values for respective values are also saved in the K2P table 132b. In this manner, it is possible to determine whether or not the values are identical by using the K2P table 132b without reading out the values.

Since the hash values may collide with one another as described above, even if hash values are identical, values have to be compared to determine whether the values are actually identical data after the values are read. Since, however, hash values cannot be different when the values are identical data, it is possible to exclude data that do not meet the condition at all at the point when the hash values are compared. With this mechanism, unnecessary reading of values is reduced, and the search speed is increased in a case of a RAM such as a NAND flash memory with a relatively low read rate.

When hash values for values are stored in the K2P table 132b as in the example of FIG. 17, hash search can be conducted by using the hash values and a RAM in which the hash values can be stored as addresses. For example, hash values are used as addresses and data are written in corresponding addresses.

In a case of a RAM in which 4 bytes of data can be stored for each address, “0x1010_{—}1010” is written as a value of “value1”. Next, “0x0101_{—}0101” is overwritten using an XOR as a value of “value2”. When the values are written to the same address, the data at the address will be “0x1111_{—}1111”. It is possible to determine that the values are identical by reading this result.

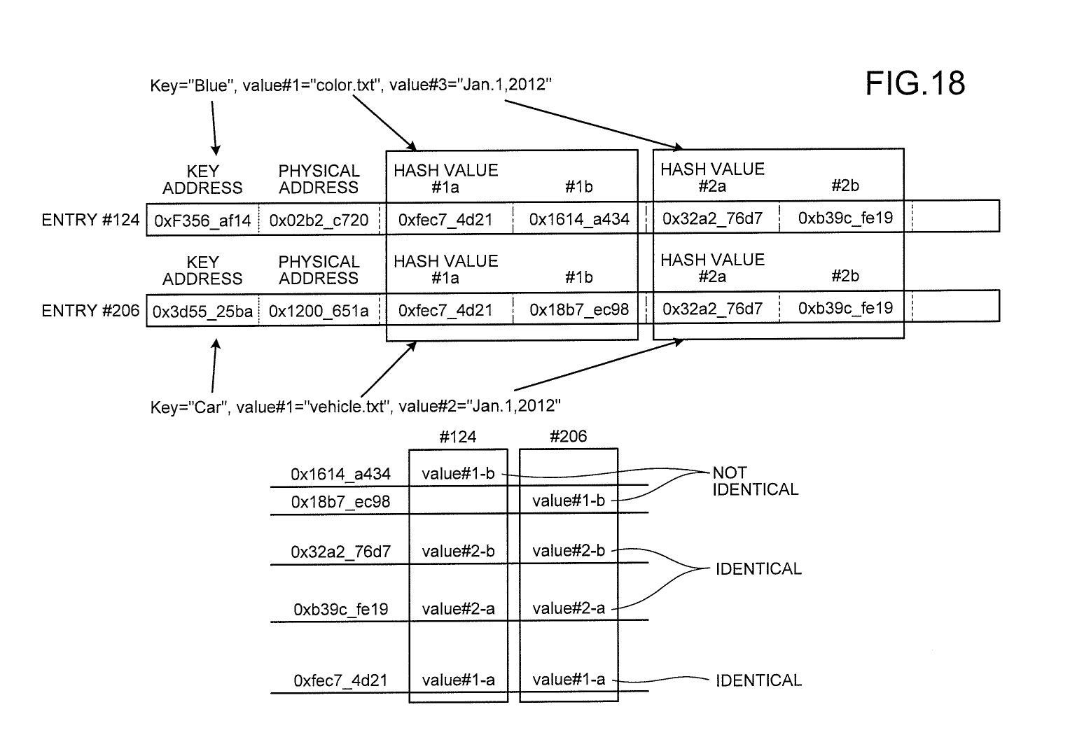

Since hash values may collide with one another as described above, it is necessary to examine the presence/absence of collision. While a result of examination by referring to values is certain, another method will be presented as an example with reference to FIG. 18. It is assumed that each value has values obtained by conversion with two or more hash functions. The example of FIG. 18 is an example in which two hash functions are used. When values are converted using different hash functions, the probability that resulting hash values become different will be higher even for values that collide when only one has function is used. The possibility of collision can therefore be reduced as much as possible. Since, however, storage of two or more hash values will cause the size of the K2P table 132b to grow, the design needs to be according to the purpose of determination whether values are identical. The condition under which hash values are identical corresponds to an AND condition of set operations.

As described above, with the semiconductor memory device according to the first embodiment, processing of retrieval of KVS data can be combined with the address management system for a nonvolatile memory. As a result, it is possible to use the K2P table in reading to refer directly to a physical address on the basis of a key without increasing the load of data management such as writing as a result of combining the KVS. It is therefore possible to eliminate L2P processing (such as access to the L2P table) in the middle that is needed in the method of the related art and perform search in a simple manner at a high speed.

### Second Embodiment

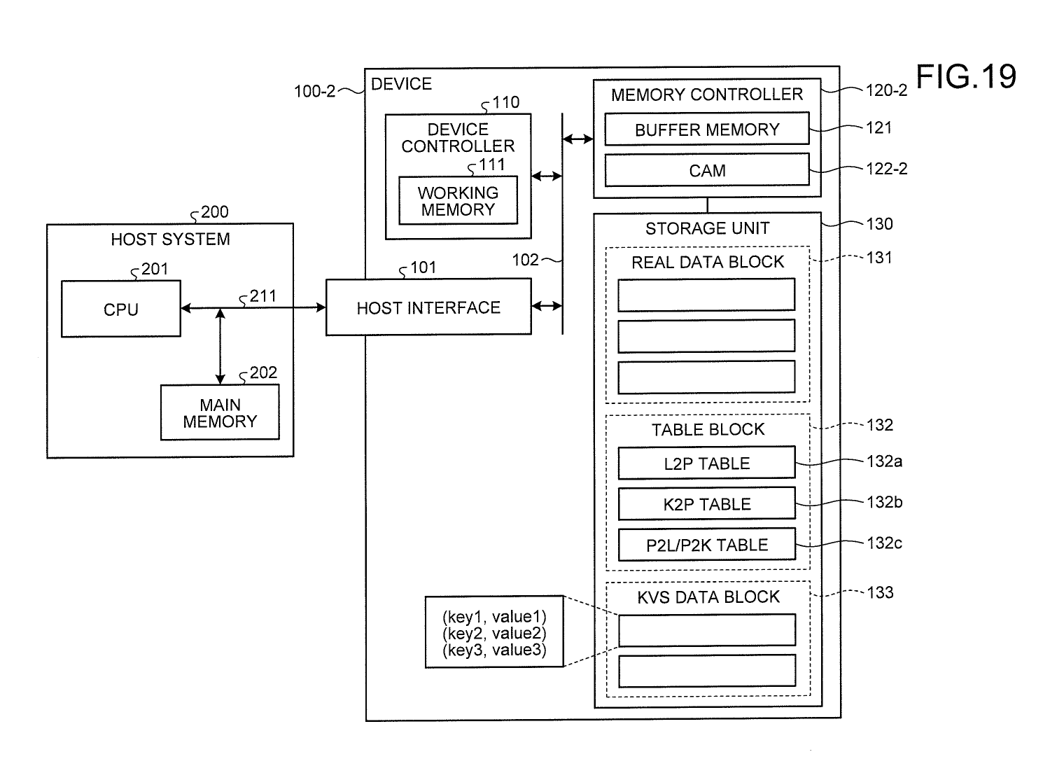

A semiconductor memory device according to a second embodiment can search for data by using a content addressable memory (CAM). FIG. 19 is a block diagram illustrating an example of a hardware configuration of a device 100-2 according to the second embodiment. As illustrated in FIG. 19, the device 100-2 includes a host interface 101, a device controller 110, a memory controller 120-2, and a storage unit 130.

The second embodiment is different from the first embodiment in that the memory controller 120-2 further includes a CAM 122B. Since the other components are similar to those in FIG. 1 of the first embodiment, the description thereof will not be repeated.

When the storage unit 130 is a NAND flash memory, a buffer memory for read/write present in the storage unit 130 may be a CAM. Specifically, any configuration in which comparison of data read from the storage unit 130 are performed by a CAM operation before the data reach the working memory 111 managed by the device controller 110 via the bus 102 in the device 100-2 may be used.

As described above, when key collision is a problem, a function of reading data from a page and determining whether a specific key is saved in the page is required. Similarly, when data are stored over a plurality of pages, a function of determining a next page pointer saved in a redundant data part of a page and outputting a control signal for reading a next page, for example, is required.

The CAM 122B used in the present embodiment is used for such functions. The CAM 122B stores KVS data read in advance. If a key is contained in the read KVS data, the CAM 122B transfers value data associated with the key as a normal value to the working memory 111. If a key is not contained, the CAM 122B returns an error signal to the device controller 110.

With this mechanism, the device controller 110 need not search for KVS data on the basis of value data in the working memory 111, for example, and the KVS operations can be performed more smoothly. The same holds true for search for a next page pointer.

For example, a next page pointer is attached to the end of a page, and stored in a real data part or a management data part. In either case, specific data (specific information) indicating the presence of a next page pointer can be searched for by using the CAM 122B. When the memory controller 120 is informed that a next page pointer is found, the memory controller 120 can successively read an address indicated by the next page pointer. Similarly to the cases above, in the case of informing the device controller 110 that a next page pointer is found, the speed is higher than the method of reading the presence of a page pointer from data in a page.

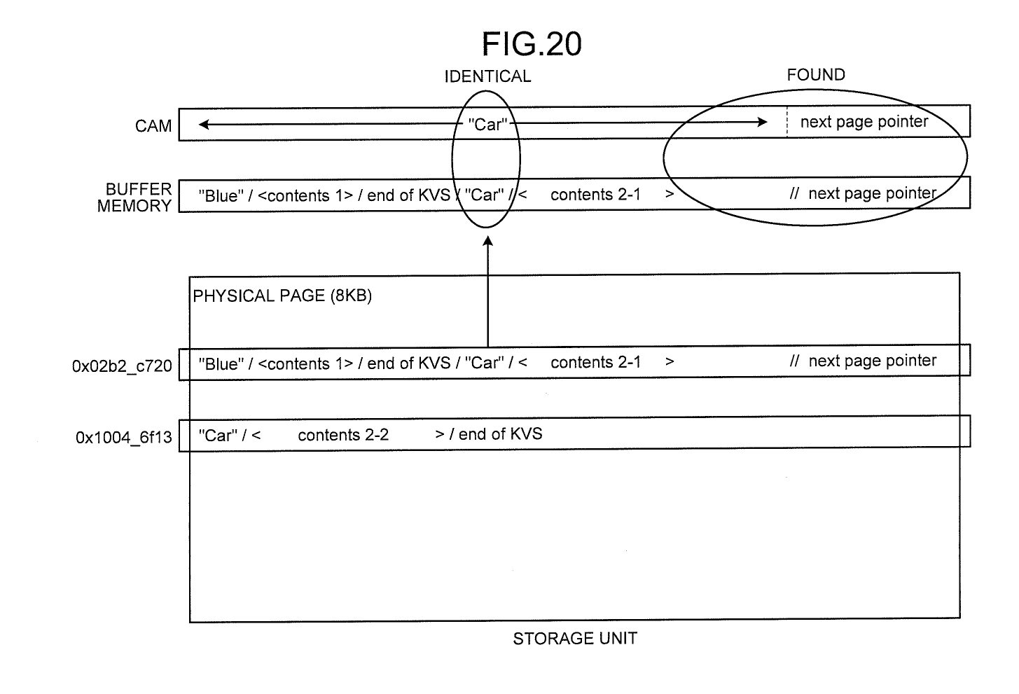

FIG. 20 is a diagram for explaining an example of search using the CAM 122B. For example, when a key “Car” is input, since the CAM 122B stores an identical key “Car”, the CAM 122B outputs “<contents 2-1>” that is a value associated with this key “Car”. Alternatively, for example, when it is found that a next page pointer is stored, the CAM 122B outputs a value stored at a location pointed by the next page pointer.

The specific data (specific information) are not limited to information indicating the presence of a next page pointer. Any information for which processing to be performed based on the specific information is determined in advance may be used.

### Third Embodiment

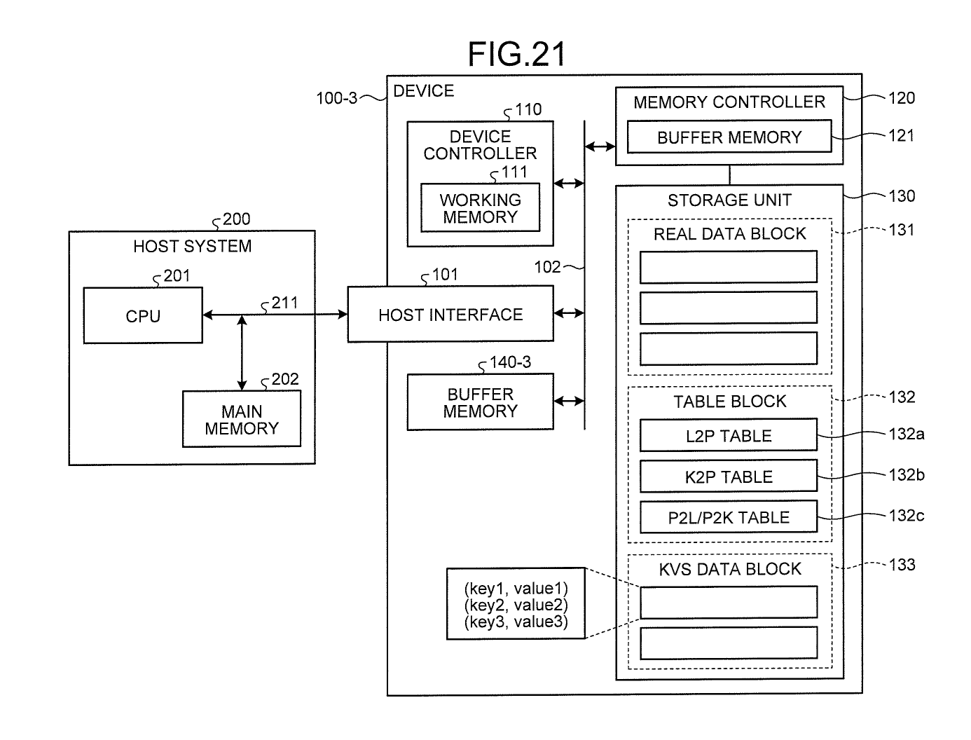

A semiconductor memory device according to a third embodiment further includes a buffer memory that has a larger size than the working memory in addition to the working memory. FIG. 21 is a block diagram illustrating an example of a hardware configuration of a device 100-3 according to the third embodiment. As illustrated in FIG. 21, the device 100-3 includes a buffer memory 140-3 in addition to a host interface 101, a device controller 110, a memory controller 120, and a storage unit 130.

The buffer memory 140-3 is a memory having a larger size than the working memory 111. The buffer memory 140-3 can be accessed from the device controller 110 via the bus 102. The buffer memory 140-3 can be a RAM such as a DRAM, an MRAM, and a PCRAM having a smaller capacity but operating at a higher speed than a NAND flash memory.

The device controller 110 transfers in advance all management tables such as the K2P table 132b and the P2K table (P2L/P2K table 132c) stored in the storage unit 130 to the buffer memory 140-3. The device controller 110 accesses and modifies data on the buffer memory 140-3. As a result, K2P processing can be performed at a higher speed than reading and writing each time from the storage unit 130.

The buffer memory 140-3 may also include a CAM similar to the CAM 122B in the second embodiment.

### Fourth Embodiment

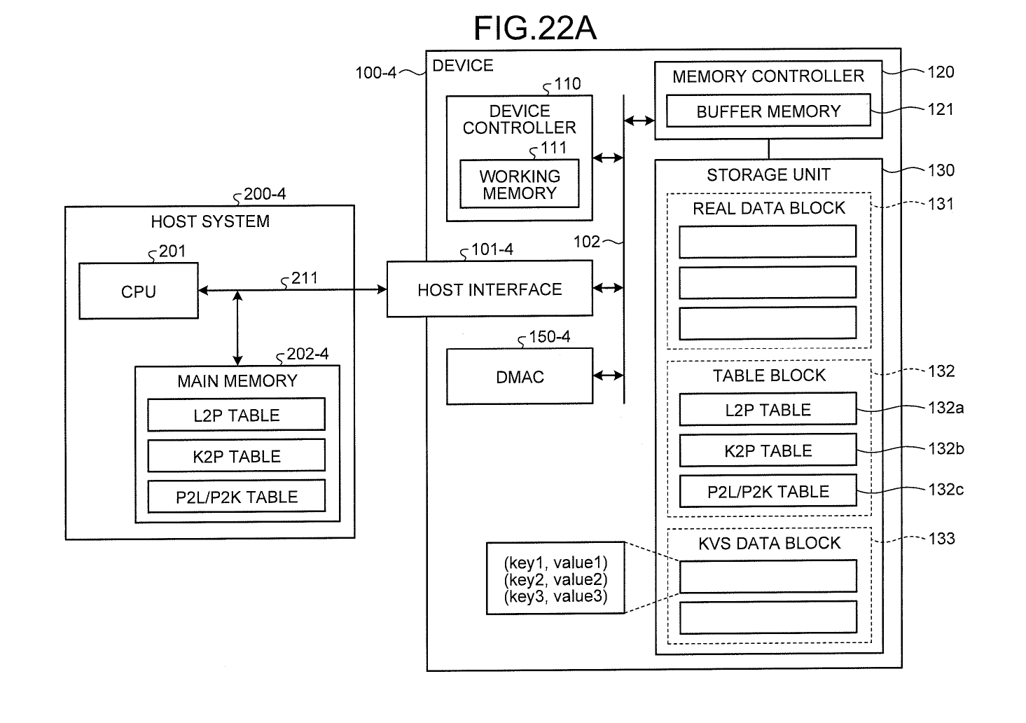

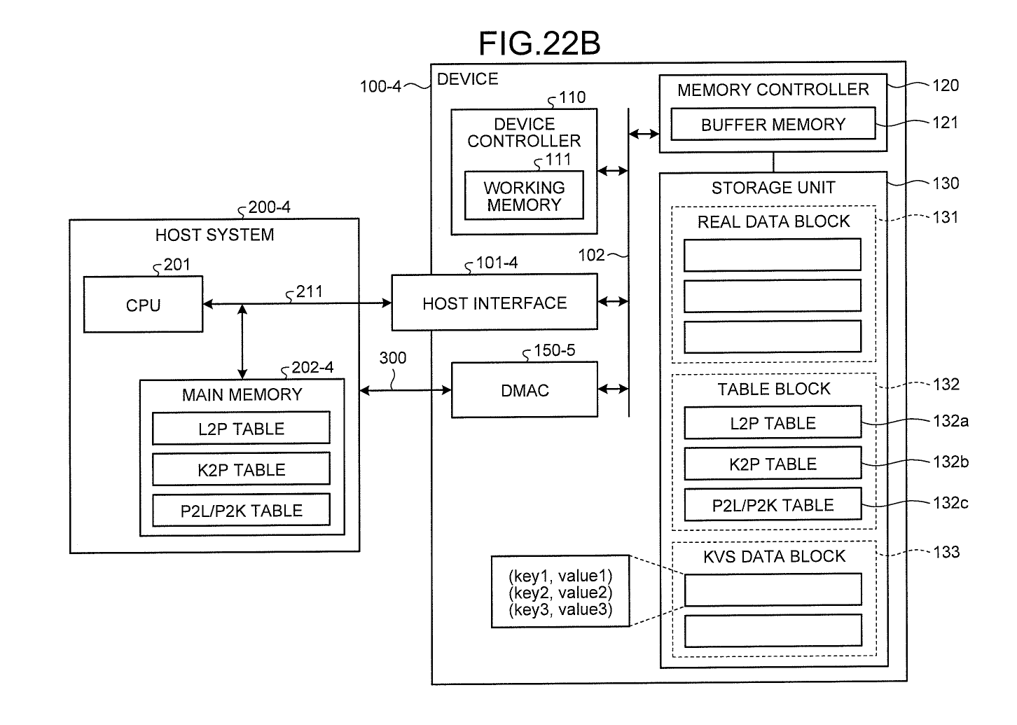

A semiconductor memory device according to a fourth embodiment further includes a direct memory access controller (DMAC). FIG. 22A is a block diagram illustrating an example of a hardware configuration of a device 100-4 according to the fourth embodiment. As illustrated in FIG. 22A, the device 100-4 includes a DMAC 150-4 in addition to a host interface 101-4, a device controller 110, a memory controller 120, and a storage unit 130.

The DMAC 150-4 allows data to be transferred to the host interface 101-4 in the device 100-4. The DMAC 150-4 transfers the L2P table 132a, the K2P table 132b and the P2L/P2K table 132c in the storage unit 130 to the host interface 101-4, for example. The host interface 101-4 receives a request for transfer of the L2P table and the K2P table from inside of the device 100-4, and transfers the tables to a main memory 202-4. The host interface 101-4 can use a DMAC if a host system 200-4 includes the DMAC. The host system 200-4 can access the transferred tables to perform K2P processing at a higher speed than reading and writing each time from the storage unit 130.

If the same data format is used for the L2P table 132a and the K2P table 132b as described above, common algorithms and commands can be used for the DMAC 150-4 and the host interface 101-4. As a result, it is possible to reduce additionally required hardware.

Modification of Fourth Embodiment

A modification of the fourth embodiment further includes another communication line 300 for connecting a host and a device to a direct memory access controller (DMAC). FIG. 22B is a block diagram illustrating an example of a hardware configuration of a device 100-5 according to the modification of the fourth embodiment. As illustrated in FIG. 22B, the device 100-5 includes a DMAC 150-5 in addition to a host interface 101-4, a device controller 110, a memory controller 120, and a storage unit 130. In addition, the DMAC 150-5 is connected to a host system 200-4 via a communication line 300 different from the host interface 101-4 to the host system 200-4 from the device 100-5.

The DMAC 150-5 can access a main memory 202-4 on the host system 200-4 side from inside the device 100-4 via the communication line 300. The DMAC 150-5 transfers the L2P table 132a, the K2P table 132b and the P2L/P2K table 132c in the storage unit 130 to the main memory 202-4, for example. The host system 200-4 can access the transferred tables to perform K2P processing at a higher speed than reading and writing each time from the storage unit 130.

If the same data format is used for the L2P table 132a and the K2P table 132b as described above, common algorithms and commands can be used for the DMAC 150-5. As a result, it is possible to reduce additionally required hardware.

### Fifth Embodiment

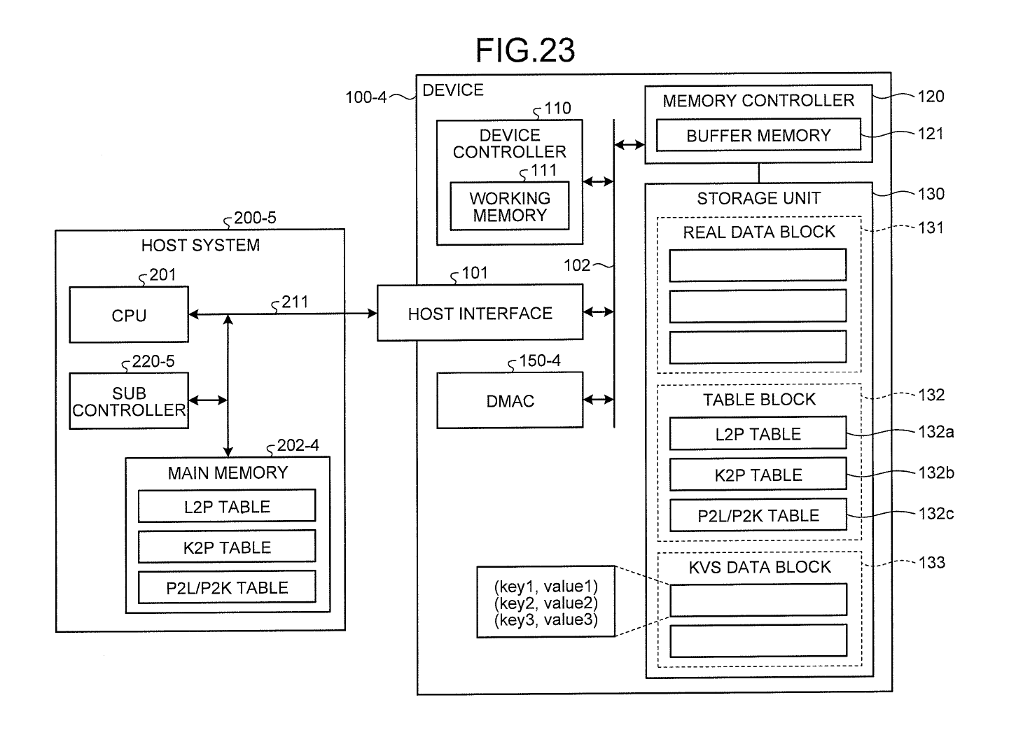

In a fifth embodiment, a host system has a function (sub controller) of performing K2P processing similar to that of a device. FIG. 23 is a block diagram illustrating an example of hardware configurations of a device 100-4 and a host system 200-5 according to the fifth embodiment. The configuration of the device 100-4 is the same as that in the fourth embodiment (FIG. 22A).

As illustrated in FIG. 23, the host system 200-5 is different from that in the fourth embodiment in that the host system 200-5 further includes a sub controller 220-5.

The sub controller 220-5 may have at least functions similar to those required for K2P processing among the functions of the device controller 110, for example. The sub controller 220-5 has a function (a function similar to that of the receiving unit 112) of receiving a request for acquiring a value associated with a key, for example. The sub controller 220-5 also has a function (a function similar to that of the acquiring unit 113) of reading various data from the main memory 202-4, for example. The sub controller 220-5 also has a function (a function similar to that of the writing unit 115) of writing various data to the main memory 202-4, for example. The sub controller 220-5 also has a function (a function similar to that of the output control unit 114) of outputting a read value as a response to an acquisition request, for example.

With such a configuration, a CPU 201 of the host system 200-5 can directly refer to the K2P table in the main memory 202-4. The CPU 201 can know the presence/absence of a key before transmitting a KVS request to the device 100-4.

A configuration in which the host system 200-4 transfers data on the device 100-4 side to the main memory 202-4 according to a predetermined rule in cooperation with the device controller 110 in the device 100-4 before transmitting a KVS request may be used. The predetermined rule is such a rule as of transferring KVS data in the device 100-4 to the main memory 202-4 to cache the data when a specific key is frequently accessed at the host system 200-4 side, for example.

For example, the device controller 110 may include a memory management unit (MMU). The memory management unit typically has a function of translating between a virtual address (logical address) and a physical address. For example, the MMU can be configured to store an L2P table, a K2P table and the like therein so that the tables in the MMU are referred to and the techniques in the embodiments described above are applied.

Furthermore, the device controller 110 may include a translation lookaside buffer (TLB). The TLB is a dedicated cache for speeding up translation from a virtual address to a physical address. For example, the TLB can be configured to store an L2P table, a K2P table and the like therein so that the tables in the TLB are referred to and the techniques in the embodiments described above are applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first storage unit configured to include a block that stores a key, a value associated with the key, a key address generated on the basis of the key and address information in which the key address and a physical address of the value are associated with each other;
a receiving unit configured to receive the key via an interface;
an acquiring unit configured to acquire the physical address associated with the key address from the address information, when the key is received by the receiving unit; and
an output unit configured to refers to the acquired physical address to output the value.

2. The device according to claim 1, further comprising a second storage unit configured to store key-value information in which a key and a value are associated with each other, and output the value associated with a specified key if the stored key-value information contains the specified key.

3. The device according to claim 2, wherein the second storage unit outputs information indicating that the specified key is not stored if the stored key-value information does not contain the specified key.

4. The device according to claim 2, wherein the second storage unit performs a process determined according to specific information and outputs a processing result if the specific information is stored therein.

5. The device according to claim 4, wherein the second storage unit outputs the value stored at a storage location if the specific information indicating the storage location of the value is stored therein.

6. The device according to claim 1, further comprising a third storage unit configured to stores the address information that is transferred from the first storage unit, the third storage unit being accessible at high speed from the first storage unit, wherein
the acquiring unit acquires the physical address on the basis of the address information stored in the third storage unit.

7. The device according to claim 1, further comprising an access controller configured to control access to a fourth storage unit that is accessible at high speed from the first storage unit, wherein
the acquiring unit refers to the address information stored in the fourth storage unit via the access controller to acquire the physical address.

8. The device according to claim 7, wherein the acquiring unit reads the address information from the first storage unit at start up and stores the read address information in the fourth storage unit.

9. The device according to claim 7, wherein the access controller controls access to the fourth storage unit via an interface different from an interface via which the request for acquisition is received.

10. The device according to claim 1, wherein the first storage unit includes the block that stores the key, the value, a fixed-length key address generated on the basis of the key, and the address information.

11. The device according to claim 1, wherein
the first storage unit includes a plurality of blocks each including a plurality of pages, and further stores a page address representing a physical address of a page in which the value is stored, the key address, and determination information indicating whether the page at the page address is valid in association with one another, and
the device further comprises a copy processing unit configured to write a valid page indicated to be valid by the determination information among pages included in a first block into a second block, and delete the valid page stored in the first block.

12. The device according to claim 1, wherein
the first storage unit includes a plurality of blocks each including a plurality of pages, and stores each page in association with a next page address representing a physical address of a page to be read next to the each page, and
after reading the each page, the acquiring unit reads the page at the next page address associated with the each page.

13. The device according to claim 1, wherein
the first storage unit further stores data different from the value, and
the address information further contains information in which a logical address of the data and a physical address of the data are associated with each other.

14. The device according to claim 1, wherein
the first storage unit stores the page address, the key address, determination information indicating whether the page at the page address is valid, and a rewrite frequency of a page at the page address in association with one another, and
the device further comprises a writing unit configured to write data into the pages in ascending order of the rewrite frequency.

15. The device according to claim 1, wherein the first storage unit includes the block that stores the key, the value, the key address, and the address information in which the key address, the physical address, and a hash value of the value are associated with one another.

16. An information processing system comprising:
a host device; and
a semiconductor memory device, wherein
the semiconductor memory device includes a first storage unit configured to include a block that stores a key, a value associated with the key, a key address generated on the basis of the key and address information in which the key address and a physical address of the value are associated with each other, and
the host device includes
a receiving unit configured to receive the key via an interface;
an acquiring unit configured to acquire the physical address associated with the key address from the address information, when the key is received by the receiving unit; and
an output unit configured to refer to the acquired physical address to output the value.

17. A control method executed in a semiconductor memory device including a first storage unit configured to include a block that stores a key, a value associated with the key, a key address generated on the basis of the key and address information in which the key address and a physical address of the value are associated with each other, the control method comprising:
receiving the key via an interface;
acquiring the physical address associated with the key address from the address information, when the key is received; and
referring to the acquired physical address to output the value.
